(19) United States
(12) Patent Application Publication
(10) Pub. No.: US 2026/0136861 A1
(43) Pub. Date: May 14, 2026

(54) WAFER CUTTING METHOD USING LASER CUTTING APPARATUS

(71) Applicant: SAMSUNG ELECTRONICS CO., LTD., Suwon-si (KR)

(72) Inventors: BYONGGOOK JEONG, Suwon-si (KR); YOUNGCHUL KWON, Suwon-si (KR); DONGJU PARK, Suwon-si (KR); JONGHO LEE, Suwon-si (KR); HYEONJUN LIM, Suwon-si (KR); NAMTAE HEO, Suwon-si (KR)

(73) Assignee: SAMSUNG ELECTRONICS CO., LTD., Suwon-si (KR)

(21) Appl. No.: 19/387,078

(22) Filed: Nov. 12, 2025

(30) Foreign Application Priority Data
Nov. 12, 2024 (KR) 10-2024-0160557
Nov. 15, 2024 (KR) 10-2024-0163192
Jan. 23, 2025 (KR) 10-2025-0010699

(51) Int. Cl. H01L 21/304; B23K 26/082; B23K 26/364; B23K 26/38; B23K 26/53; B23K 101/40; H01L 21/683

(52) U.S. Cl. CPC H10P 52/00; B23K 26/082; B23K 26/364; B23K 26/38; B23K 26/53; H10P 72/7402; B23K 2101/40; H10P 72/7416

(57) ABSTRACT

A wafer cutting method includes forming a plurality of grooves by scanning a laser beam onto a front surface of a wafer, wherein the wafer comprises a plurality of layers, and the laser beam comprises at least two lights; polishing a rear surface of the wafer, mounting the wafer on a dicing tape, and cutting the wafer by expanding the dicing tape, wherein the forming the plurality of grooves includes forming at least two grooves by using the at least two lights, the at least two grooves having different widths on at least two layers, among the plurality of layers of the wafer.

### CROSS-REFERENCE TO RELATED APPLICATIONS

This application is based on and claims priority under 35 U.S.C. § 119 to Korean Patent Application Nos. 10-2024-0160557, filed on Nov. 12, 2024, 10-2024-0163192, filed on Nov. 15, 2024, and 10-2025-0010699 filed on Jan. 13, 2025, in the Korean Intellectual Property Office, the disclosures of which are herein incorporated by reference in their entireties.

### BACKGROUND

Embodiments of the present disclosure described herein relate to a method for cutting a wafer by using a laser cutting apparatus.

A plurality of semiconductor chips are formed together on a semiconductor substrate, such as a wafer, and a singulation process may be performed to separate them from each other. In addition, in order to improve productivity with the rapid development of the electronics industry, semiconductor packages including a plurality of semiconductor chips are also formed together by using a semiconductor substrate, such as a wafer, or are formed together by attaching them to a support substrate, and then performing a singulation process.

Recently, as the complexity of semiconductor devices has increased, the singulation process of various semiconductor chips has become essential, and a method for efficiently cutting wafers without defects is required.

### SUMMARY

Embodiments of the present disclosure provide a wafer cutting method using a laser cutting apparatus having a high reliability.

According to an aspect of an example embodiment, a wafer cutting method includes forming a plurality of grooves by scanning a laser beam onto a front surface of a wafer, wherein the wafer comprises a plurality of layers, and the laser beam comprises at least two lights; polishing a rear surface of the wafer, mounting the wafer on a dicing tape, and cutting the wafer by expanding the dicing tape, wherein the forming the plurality of grooves includes forming at least two grooves by using the at least two lights, the at least two grooves having different widths on at least two layers, among the plurality of layers of the wafer.

According to an aspect of an example embodiment, a wafer cutting method includes polishing a rear surface of a wafer, the wafer comprising a plurality of layers, mounting the wafer on a dicing tape, forming a plurality of grooves by scanning a laser beam onto a front surface of the wafer, the laser beam comprising at least two lights; and cutting the wafer by expanding the dicing tape, wherein the forming the plurality of grooves comprises forming at least two grooves having different widths on at least two layers, among the plurality of layers of the wafer, by using the at least two lights.

### BRIEF DESCRIPTION OF FIGURES

The above and other objects and features of the present disclosure will become apparent by describing in detail example embodiments thereof with reference to the accompanying drawings.

FIG. 1 is a block diagram illustrating a laser cutting apparatus according to an embodiment of the present disclosure.

FIG. 2 is a block diagram illustrating a laser cutting apparatus according to an embodiment of the present disclosure.

FIG. 3 is a block diagram illustrating a laser cutting apparatus according to an embodiment of the present disclosure.

FIG. 4 illustrates a process of scanning modulated beams in a process of cutting a wafer by using a laser cutting apparatus according to the embodiment of FIG. 3.

FIG. 5 is an enlarged view of beams corresponding to portion P1 of FIG. 4.

FIG. 6 is a block diagram illustrating a laser cutting apparatus according to an embodiment of the present disclosure.

FIGS. 7A to 7C are schematic views illustrating splitting of beams using a two-dimensional beam splitting optical system according to an embodiment.

FIG. 8 illustrates an etching state of a wafer when the beams of FIG. 7C are irradiated onto the wafer together.

FIGS. 9A to 9C are schematic views illustrating splitting of beams using a two-dimensional beam splitting optical system according to an embodiment.

FIG. 10 illustrates the beams of FIG. 9C, and illustrates an etching state of a wafer when the beams are irradiated onto the wafer together.

FIG. 11 is a block diagram illustrating a laser cutting apparatus according to an embodiment of the present disclosure.

FIG. 12 illustrates one of the beams of the laser cutting apparatus of FIG. 11.

FIG. 13 is a block diagram illustrating a laser cutting apparatus according to an embodiment of the present disclosure.

FIG. 14 illustrates one of the beams exiting the laser cutting apparatus of FIG. 13.

FIG. 15 is a block diagram illustrating a laser cutting apparatus according to an embodiment of the present disclosure.

FIG. 16 is a schematic view illustrating secondary splitting of some of the beams split by a first birefringent optical system of the present disclosure.

FIG. 17 is a flowchart illustrating a method for processing a semiconductor element according to an embodiment.

FIGS. 18A to 18E are schematic views sequentially illustrating a method for processing a semiconductor element.

FIGS. 19A and 19B are views illustrating a wafer including a substrate and an element layer.

FIG. 20 is a flowchart illustrating a method for processing a semiconductor element according to an embodiment.

FIGS. 21A to 21E are schematic views sequentially illustrating a method for processing a semiconductor element.

FIG. 22 is a schematic view illustrating operations of processing a wafer by using a laser.

FIG. 23 is a schematic view illustrating operations of processing a wafer by using a laser.

FIGS. 24A and 24B are schematic views illustrating operations of processing a wafer having a plurality of element layers by using a laser.

FIGS. 25A to 25E are schematic views illustrating a method for processing a wafer according to an embodiment of the present disclosure.

FIGS. 26A and 26B are schematic views illustrating a method for processing a wafer according to an embodiment of the present disclosure.

FIG. 27A illustrates a presence or an absence of grooving defects in a form of areas depending on laser irradiation conditions when grooves are to be formed in an element layer, and FIG. 27B illustrates a presence or an absence of grooving defects in a form of areas according to laser irradiation conditions when grooves are to be formed in a substrate layer.

FIG. 28 is a schematic view illustrating a semiconductor element manufactured through the above-described method for manufacturing a semiconductor device.

FIGS. 29A and 29B are schematic views illustrating a semiconductor element manufactured by using the method for manufacturing semiconductor element.

FIGS. 30A to 30E are schematic views illustrating, by way of example, semiconductor elements manufactured by using a method for manufacturing semiconductor elements according to the present disclosure.

FIG. 31A is a cross-sectional view illustrating a semiconductor element according to an embodiment of the present disclosure, and FIG. 31B is a cross-sectional view specifically illustrating the semiconductor element of FIG. 31A.

FIGS. 32A to 32E are views illustrating a method for manufacturing a semiconductor element.

FIG. 33 illustrates semiconductor devices manufactured through the above-described method.

FIG. 34 illustrates a semiconductor package according to an embodiment of the present disclosure.

FIG. 35 illustrates a semiconductor package according to an embodiment of the present disclosure.

### DETAILED DESCRIPTION

Embodiments of the present disclosure may include a semiconductor element manufacturing apparatus used for manufacturing a semiconductor element, a method for manufacturing a semiconductor element by using the apparatus, and a semiconductor element manufactured through the method for manufacturing a semiconductor element.

A semiconductor element may be manufactured by forming semiconductor elements, such as integrated circuits, on a surface of a substantially disk-shaped semiconductor substrate (e.g., a silicon wafer), and then cutting the semiconductor elements along divided areas with a laser cutting apparatus. Hereinafter, a semiconductor substrate, on which semiconductor elements are formed on an upper surface or an interior thereof, including a semiconductor substrate, on which semiconductor elements are not formed, will be referred to as a wafer.

First, a laser cutting apparatus will be described first, and a method for manufacturing a semiconductor chip by using the laser cutting apparatus and a semiconductor device manufactured by using the same will be described sequentially. Hereinafter, embodiments of the present disclosure will be described in detail with reference to the accompanying drawings.

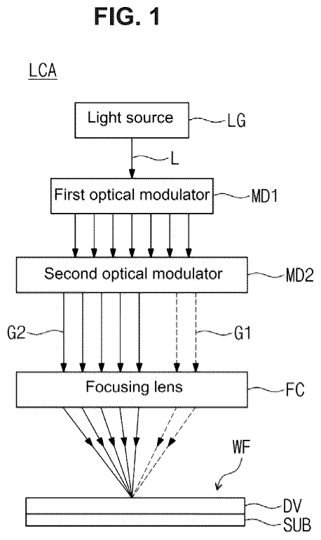

FIG. 1 is a block diagram illustrating a laser cutting apparatus LCA according to an embodiment of the present disclosure.

Referring to FIG. 1, the laser cutting apparatus LCA may be an apparatus that cuts a target object, for example, a wafer WF by using a laser. The wafer WF may include a substrate layer SUB and at least one element layer DV that is provided on the substrate layer SUB, and may be cut to form at least one semiconductor chip. That is, semiconductor chips may be manufactured by cutting the wafer WF.

The laser cutting apparatus LCA may include a light source LG, a first optical modulator MD1, a second optical modulator MD2, and a focusing lens FC.

The light source LG may be a laser generator, and may generate a laser beam “L” of femtosecond pulses. The laser beam “L” may be a laser having a short pulse width of about 10 to 15 seconds. However, a type of the laser beam “L” is not limited thereto. For example, the light source LG may generate a laser beam of picosecond pulses.

The light source LG may include a laser gain medium for oscillating a laser beam “L” and a nonlinear crystal medium that modulates a wavelength thereof. The laser gain medium may include a solid medium or a non-solid medium. Properties of the laser beam “L” may vary depending on the laser gain medium. For example, the laser gain medium may include a neodymium yttrium aluminum garnet compound (Nd:yAG), a neodymium yttrium orthovanadate compound (Nd:yVO₄), an aluminum gallium arsenide compound (AlGaAS), an aluminum gallium indium compound (AlGaInP), a gallium nitride compound (GaN), a neodymium optical fiber (Nd-Fiber), sapphire, and/or the like. In an embodiment, the nonlinear crystal medium may include a KTiOPO₄ (KTP) crystal.

The laser beam “L” may be applied to a target point of a target object, for example, the wafer WF, to form a groove through laser ablation. A focus generated by the laser beam “L” may be formed on a surface of the target object or at a point that is close to the surface of the target object. A focus spot of the laser beam “L” may be located at the target point (for example, a surface of the wafer WF, a specific depth from the surface of the wafer WF, or an upper side of the surface of the wafer WF). The focus spot of the laser may be scanned along one direction on the surface of the target object. A scan direction may correspond to a cutting line for cutting the target object.

The laser beam “L” generated by the light source LG may have a laser power in a range of about 1 W to about 100 W, or about 10 W to about 70 W, a laser pulse duration in a range of about 100 fs to about 500 ps, or about 500 fs to about 500 ps, a laser pulse repetition rate in a range of about 10 kHz to about 2000 kHz, a nominal pulse energy in a range of about 50 μJ to about 300 μJ, a laser wavelength in a range of about 300 nm to about 1100 nm, and a laser scan speed in a range of about 10 mm/s to about 3000 mm/s.

For example, to minimize generation of a heat affected zone, the laser beam “L” generated by the light source LG may have a laser power in a range of about 30 W to about 70 W, a laser pulse duration in a range of about 200 fs to about 15 ps, a laser pulse repetition rate in a range of about 300 kHz to about 3 MHz, a nominal pulse energy in a range of about 80 μJ to about 200 μJ, a wavelength in a range of about 330 nm to about 600 nm, and a laser scan speed in a range of about 50 mm/s to about 2000 mm/s.

In another embodiment, to minimize the generation of the heat affected zone, the laser beam “L” generated by the light source LG may have a laser power in a range of about 0.1 W to about 30 W, a laser pulse duration in a range of about 500 fs to about 50 ps, a laser pulse repetition rate in a range of about 100 kHz to about 1000 kHz, a nominal pulse energy in a range of about 0.1 μJ to about 200 μJ, the wavelength in the range of about 330 nm to about 600 nm, and the laser scan speed in the range of about 50 mm/s to about 2000 mm/s.

The first optical modulator MD1 may be a beam splitting optical system that splits the laser beam “L” that exits the light source LG into a plurality of beams. The first optical modulator MD1 may split the exiting laser beam “L” into the plurality of beams along the scan direction of the laser. When a direction, in which the laser beam “L” is scanned, is assumed to be a y-axis direction and a direction that is perpendicular to the scan direction is assumed to be an x-axis direction, the first optical modulator MD1, for example, may split the laser beam “L” into a plurality of beams that is split along the y axis.

FIG. 1 illustrates that light that exits the light source LG is split into seven beams, but this is for convenience of description, and the first optical modulator MD1 may split the laser beam “L” into a smaller or larger number of beams. Through splitting in a direction (e.g., the y-axis direction), in which scanning is performed, a defect (e.g., a heat affected zone (HAZ)) due to heat may be minimized even when the laser beam “L” is provided to the wafer WF.

The first optical modulator MD1 may split the laser beam “L” that exits the light source LG into a plurality of beams, and may include a beam splitter (e.g., a one-dimensional diffractive optical element DOE) and/or at least one optical lens. However, the first optical modulator MD1 is not limited thereto.

The second optical modulator MD2 may modulate the split beams into beams of a plurality of groups having different properties. In an embodiment, the second optical modulator MD2 may modulate some of the split beams to modulate the split beams into two groups having different properties, that is, beams G1 of a first group and beams G2 of a second group. The beams G1 of the first group may be beams that are modulated by the second optical modulator MD2, and the beams G2 of the second group may be original beams that are not modulated.

FIG. 1 illustrates, as an example, that the light that exits the light source LG is split into a total of seven beams, and among the split beams, five beams are maintained as is without being modulated, and the remaining two beams are modulated. Here, the five unmodulated beams may correspond to the beams G2 of the second group, and the one modulated beam may correspond to the beams G1 of the first group.

In an embodiment of the present disclosure, the different properties of the beams may mean differences in waveforms of the beams, additional splitting, differences in temporal and spatial spacings between the additionally split beams, polarization, birefringence, and/or the like. The differences in the waveforms may include differences in peak shapes of the laser beams. The differences in the peak shapes may include variations in a full width at half maximum, differences in a shape of a peak top (e.g., a Gaussian shape or a flat-top shape), and whether the shape is symmetric or asymmetric. Hereinafter, the waveform of the laser beam means an intensity distribution of the laser beam on the x axis.

In an embodiment, the beams G1 of the first group may have a different waveform compared to that of the beams G2 of the second group. For example, the beams before the modulation, e.g., the beams G2 of the second group may have a Gaussian shape, and the beams after the modulation, e.g., the beams G1 of the first group may have a flat top shape. Alternatively, the beams G1 of the first group may have a different full width at half maximum compared to the beams G2 of the second group. For example, the beams G1 of the first group may have a larger full width at half maximum than that of the beams G2 of the second group. In an embodiment, the beams G1 of the first group may have the same waveform as that of the beams G2 of the second group, but may be split in a different direction. Alternatively, the beams G1 of the first group may be polarized in a different direction than that of the beams G2 of the second group. Alternatively, the beams G1 of the first group may be birefringed and further split into two beams that propagate in a different form from that of the beams G2 of the second group.

In an embodiment, the second optical modulator MD2 may modulate all of the laser beams “L” that are incident on the second optical modulator MD2 into lights having different properties. Alternatively, the second optical modulator MD2 may modulate only a portion of the light that is incident on the second optical modulator MD2 to create light having different properties from the unmodulated remainders.

In an embodiment, the second optical modulator MD2 may modulate light of some of the split beams and additionally modulate light of some of the remaining split beams. For example, the beams G1 of the first group may be modulated two or more times to have two or more different properties. For example, the beams G1 of the first group may have different waveforms and polarization directions from those of the beams G2 of the second group.

In an embodiment, the beams that have passed through the second optical modulator MD2 may include a first group G1 including unmodulated beams, a second group G2 including modulated beams, and a third group (not illustrated), and the beams of the second group G2 and the third group may have different properties. For example, the first group G1 may be unmodulated Gaussian beams, the second group G2 may be Gaussian beams having a full-width at half maximum that is larger than that of the beams G1 of the first group, and the third group may be flat-top beams.

A number of groups of beams with different properties that the second optical modulator MD2 may modulate is not limited thereto, and it is apparent that the second optical modulator MD2 may modulate the beams into a greater number of different groups of beams.

In an embodiment, the second optical modulator MD2 may modulate the beams such that beams of respective groups have different areas. In particular, the second optical modulator MD2 may modulate the beams into beams having different areas depending on the groups that are placed ahead and the groups that are placed behind in consideration of the direction, in which the scanning is performed. Here, being placed ahead or behind of the scan direction may mean being placed or behind temporally and/or spatially.

In terms of space, when the scan direction of the laser beams “L” is indicated by an arrow, it may be seen that a group that is closer to a head of the arrow spatially is placed ahead of a group that is closer to a tail of the arrow. In terms of time, when the scanning of the laser beams “L” is performed and the scan direction of the laser beams “L” is indicated by an arrow, the beams of a group that is closer to the head of the arrow may be applied to the target point of the target object first, and a group that is closer to the tail of the arrow may be applied to the target point of the target object later.

However, even when the laser beams “L” are temporally and/or spatially split, a degree of temporal/spatial spacing may not be large, and there may be an overlap between two adjacent beams. For this reason, even when the beams are temporally and/or spatially split, in reality, distinction between the individual beams may not be completely clear, and there may be no significant difference from functioning as a single applied light.

In a description of the seven beams again as an example with reference to the illustrated drawings, a single laser beam “L” output from the light source LG may be split into seven spatially split beams. In this case, the seven split beams may be modulated into two beams G1 of the first group and five beams G2 of the second group that are spatially split after passing through a second optical modulator MD2.

In an embodiment, the beams G1 of the first group and the beams G2 of the second group may not be temporally split and may exit simultaneously. However, the beams G1 of the first group may be positioned spatially closer to the head of the arrow in the scan direction than the beams G2 of the second group, and thus the beams G1 of the first group may reach the target point first when the laser scanning is performed.

Alternatively, in another embodiment, the seven beams of the first group G1 and the second group G2 may be temporally split, and thus, may exit at different times. For example, the beams G1 of the first group may be irradiated to the target point first, and the beams G2 of the second group may be irradiated to the target point later.

In an embodiment, when the scanning is performed, the beams of a group that are first irradiated to a target point may have a wider area. In other words, when the scanning is performed and “n” groups are sequentially disposed from a group placed ahead, the area of the beams of the first group may be the largest, and the areas of the beams of remaining group(s) placed behind may sequentially decrease in subsequent order. For example, when the beams G1 of the first group are placed ahead of the beams G2 of the second group, the area of the beams G1 of the first group may be larger than the area of the beams G2 of the second group.

In an embodiment, the second optical modulator MD2 may modulate the beams of each group into beams having different widths in a direction (for example, the x direction) that is perpendicular to the scan direction. In particular, the second optical modulator MD2 may modulate the beams into beams having different widths depending on the groups that are placed ahead and the groups that are placed behind in consideration of the direction, in which the scanning is performed. When the scanning is performed and “n” groups are sequentially disposed from a group placed ahead, the width of the beams of the first group may be the largest, and the widths of the beams of remaining group(s) placed behind may sequentially decrease in subsequent order. In an embodiment, when the beams G1 of the first group are placed ahead of the beams G2 of the second group when the laser scanning is performed, the width of the beams G1 of the first group may be greater than the width of the beams G2 of the second group.

The beams modulated by the second optical modulator MD2 may be concentrated through a focusing lens FC and may be applied to the target object, that is, the wafer WF.

The laser cutting apparatus LCA having the above-described configuration may simultaneously apply beams of a plurality of spatially disposed groups, for example, the beams G1 of the first group and the beams G2 of the second group, to the target object through a single scan. Because the beams of respective groups have different areas (e.g., widths), lasers having different areas (e.g., widths) may be simultaneously or sequentially applied to the target point of the target object. Beams having a large area (e.g., width) may etch the target point in a large area (e.g., width), and the beams having a small area (e.g., width) may etch the target point in a small area (e.g., width). Through this, a cutting structure having a large area (e.g., width) and a small area (e.g., width) may be provided to the target point of the target object through a single scan.

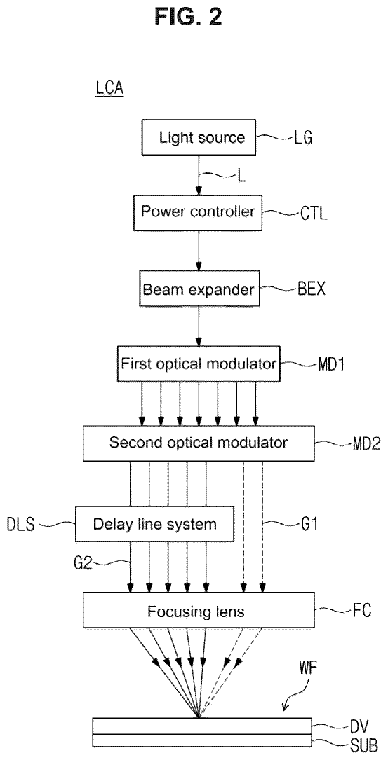

FIG. 2 is a block diagram illustrating a laser cutting apparatus LCA according to an embodiment of the present disclosure. In the following embodiments, differences from the above-described embodiment will be mainly described to avoid a repeated description.

Referring to FIG. 2, the laser cutting apparatus LCA may further include a power controller CTL, a beam expander BEX, and/or a delay line system DLS.

The power controller CTL may control an intensity of a laser beam that exits the light source LG, and the beam expander BEX may expand the laser beam that exits the light source LG. The power controller CTL and the beam expander BEX may be provided between the light source LG and the first optical modulator MD1.

The delay line system DLS may be provided between the second optical modulator MD2 and the focusing lens FC.

The delay line system DLS may be used for temporal synchronization or desynchronization of the beams G1 of the first group and the beams G2 of the second group, and may control temporal exit order of the beams G1 of the first group and the beams G2 of the second group. For example, when a first light LS1 is delayed through a modulation process of the beams in the first and second optical modulators MD1 and MD2, the beams G2 of the second group may also be delayed to be synchronized with the beams G1 of the first group. Alternatively, incidence timings of the beams G1 of the first group and the beams G2 of the second group may be adjusted to different degrees.

Although not illustrated, the laser cutting apparatus LCA may include additional components in addition to the components described above. For example, the laser cutting apparatus LCA may include at least one lens, at least one prism, at least one mirror, a band pass filter, and/or the like that may change or control a path of light.

Furthermore, although not illustrated, the components may be physically and/or electrically connected to a controller (not illustrated) and operations thereof may be controlled by the controller. In an embodiment, the controller may be implemented by using computer components. The controller may include, for example, a central processing unit (CPU) that performs calculations according to a control program, a read-only memory (ROM) that stores the control program, a random access memory (RAM) that may allow recording for temporarily storing detected values, calculation results, and/or the like, and reading, an input interface, and/or an output interface.

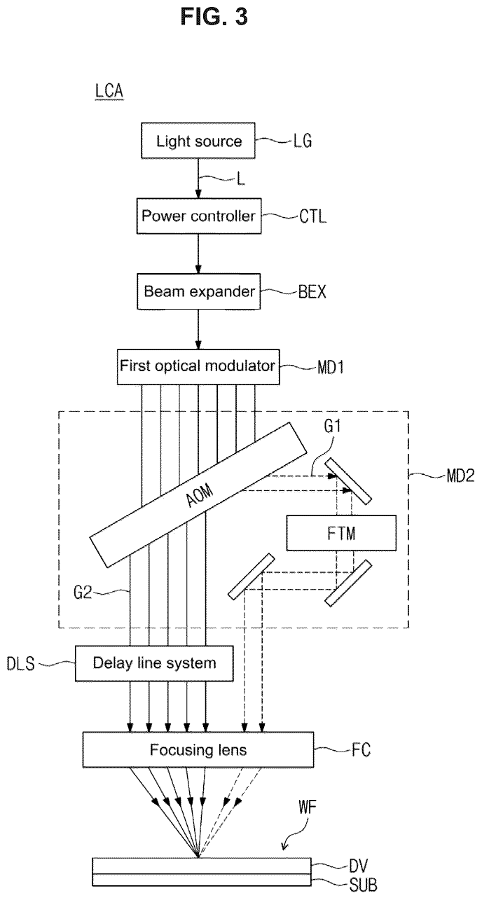

FIG. 3 is a block diagram illustrating a laser cutting apparatus LCA according to an embodiment of the present disclosure.

Referring to FIG. 3, the laser cutting apparatus LCA may include an acousto-optic modulator AOM, and a flat top modulator FTM as one of the optical modulators.

The acousto-optic modulator AOM may be an optical deflection adjustment device that temporally divides beams split in a first optical modulator MD1 and deflects the optical axes of the beams to a specific direction. The beams that have passed through the acousto-optic modulator AOM may be modulated into a plurality of beams having different optical axes.

The acousto-optic modulator AOM may modulate amplitudes (or frequencies) of the beams using an acousto-optic effect, and/or may deflect the beams to a specific direction. That is, by using a diffraction effect of light, the amplitude, frequency, phase, polarization, spatial position, and/or optical axis of the beams may be changed.

More specifically, the acousto-optic modulator AOM may include an acousto-optic element that deflects the optical axes of the beams to a specific direction, an radio frequency (RF) oscillator that generates radio frequency (RF) that is to be applied to the acousto-optic element, an RF amplifier that amplifies power of the RF generated by the RF oscillator and applies the amplified power to the acousto-optic element, a deflection angle adjuster that adjusts a frequency of the RF generated by the RF oscillator, and an output adjuster that adjusts an amplitude of the RF generated by the RF oscillator. The acousto-optic element may adjust an angle for deflecting optical paths of the beams in response to the frequency of the applied RF, and may adjust an output of a pulsed laser beam in response to the amplitude of the applied RF. For example, the modulation of the acousto-optic modulator AOM may be made by an RF signal of 1 MHz or more, and different directivities may be selectively given to various numbers of incident beams.

In an embodiment, the acousto-optic modulator AOM may be disposed at an angle relative to the incident light such that the split beams are incident on the acousto-optic modulator AOM at different timings. For example, the acousto-optic modulator AOM may be disposed at an angle of about 45 degrees relative to propagation directions of the split beams. As the acousto-optic modulator AOM is disposed to be inclined, the beams may be incident on the acousto-optic modulator AOM with a time difference.

The acousto-optic modulator AOM may cause the beams G1 of the first group and the beams G2 of the second group to be deflected with different optical axes. Accordingly, the deflected beams G1 of the first group and the beams G2 of the second group may travel in different paths.

The flat top modulator FTM may be provided on a path of the beams G1 of the first group. The flat top modulator FTM may modulate a waveform of the beams G1 of the first group.

In an embodiment, the flat top modulator FTM may modulate the beams G1 of the first group into flat top light instead of Gaussian light. The flat top light may be referred to as U-shaped light. The flat top modulator FTM may generate a flat beam by expanding each Gaussian beam and then shielding an outskirt thereof. Alternatively, the flat top modulator FTM may split the Gaussian beam into a plurality of beams and then modulate them into flat beams by causing them to overlap each other.

In an embodiment, the beams G1 of the first group may be placed ahead and the beams G2 of the second group may be placed behind along the scan direction. In this case, the beams G2 of the second group may have a Gaussian form, and the beams G1 of the first group may have a flat top form with a larger width than that of the beams G2 of the second group.

In an embodiment, outputs of the beams G1 of the first group and the beams G2 of the second group may be independently controlled by the controller. That is, the controller may control the output of the beams G1 of the first group and/or the beams G2 of the second group. In an embodiment, the controller may control only the output of the beams G2 of the second group. When the controller may control the output of only the beams of a specific group, various cutting processes may be set up by variously combining the groups.

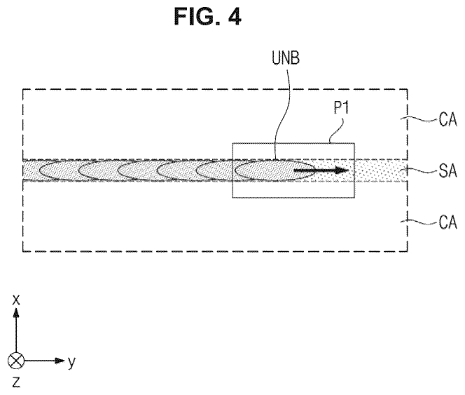

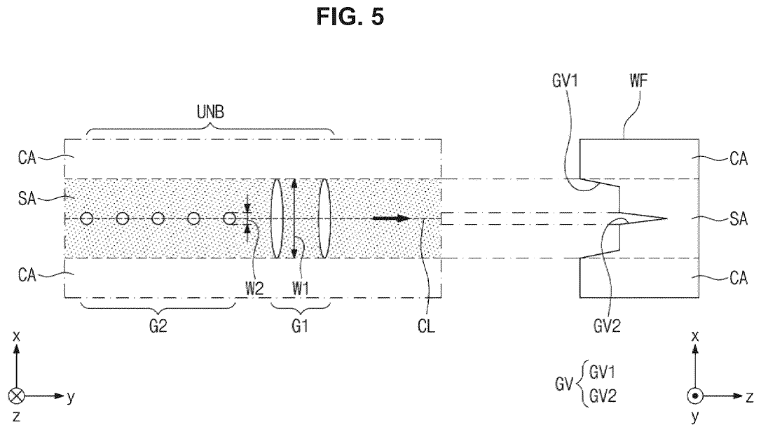

FIG. 4 illustrates a process of scanning modulated beams in a process of cutting a wafer WF by using a laser cutting apparatus according to the embodiment of FIG. 3. FIG. 5 is an enlarged view of beams corresponding to portion P1 of FIG. 4, and illustrates an etching state of the wafer WF when the beams are irradiated on the wafer WF together.

Referring to FIGS. 4 and 5, the beams that exit the laser cutting apparatus may be output onto the wafer WF along the scan direction.

The wafer WF may include chip areas CA, in which semiconductor elements are provided, and scribe lane areas SA, in which the semiconductor elements are disposed in the chip areas CA and then cutting is performed. The exiting beams may be scanned along the cutting line CL in the scribe lane area SA. The cutting line CL may be an imaginary line, along which cutting is performed.

In the laser cutting apparatus, when the beams that exit at the same time with a single output are assumed to be unit beams UNB, the unit beams UNB irradiated sequentially may overlap each other in an area that is to be processed. The laser cutting apparatus may cut the wafer WF by sequentially providing the unit beams UNB while being moved along each scan direction.

Each unit beam UNB may include a plurality of beams that are modulated by an optical modulator MD. As illustrated in FIG. 5, each unit beam may include the beams G1 of the first group and the beams G2 of the second group, and the beams G1 of the first group may be placed ahead and the beams G2 of the second group may be positioned behind along the scan direction. Because the beams G2 of the second group have a Gaussian form, and thus, may be provided in a spot form. The beams G1 of the first group may be provided in a flat top form having a larger width in the x direction than that of the beams G2 of the second group. Here, the width of the beams G1 of the first group in the y-axis direction may be substantially the same as the width of the beams G2 of the second group in the y-axis direction.

When the width of the beams G1 of the first group in the x direction is assumed to be a first width W1, and the width of the beams G2 of the second group in the x direction is assumed to be a second width W2, the first width W1 may be greater than the second width W2.

When the beams are irradiated onto the wafer WF along the y direction, the wafer WF may be etched by the beams. The wafer WF may be etched in a depth direction from a surface of the wafer WF. Here, the depth direction from the surface of the wafer WF may correspond to the z direction (or the z-axis direction) that is perpendicular to the x direction and the y direction.

As the beams are scanned, a first groove GV1 corresponding to the width of the beams G1 of the first group may be first formed on the wafer WF. Next, the beams G2 of the second group that are placed behind are irradiated along the scan direction, and a second groove GV2 having a width corresponding to the width of the beams G2 of the second group may be formed on the wafer WF. The first groove GV1 and the second groove GV2 may be formed to have sizes corresponding to the first width W1 and the second width W2, respectively.

Here, because the beams G1 of the first group are provided first and then the beams G2 of the second group are provided, the first groove GV1 may be formed first in the wafer WF and then the second groove GV2 may be formed within the first groove GV1.

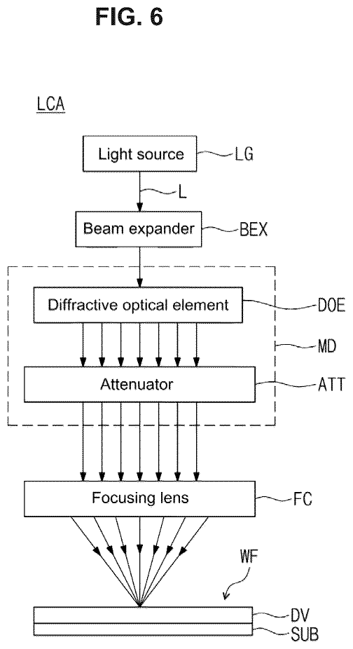

FIG. 6 is a block diagram illustrating a laser cutting apparatus LCA according to an embodiment of the present disclosure.

Referring to FIG. 5, the laser cutting apparatus LCA may include a two-dimensional diffractive optical element DOE, and an attenuator ATT as an optical modulator MD.

A two-dimensional diffractive optical element DOE may be a two-dimensional beam splitting optical system that may split light that exits the light source LG into a plurality of two-dimensionally disposed beams.

In an embodiment, the two-dimensional diffractive optical element DOE may simultaneously split a plurality of beams along the x axis and the y axis. However, an embodiment is not limited thereto, and an x-axis beam splitting optical system that splits the beams along the x-axis direction and a y-axis beam splitting optical system that splits the beams along the y-axis direction may be disposed together separately. The x-axis beam splitting optical system and the y-axis beam splitting optical system may be sequentially disposed to first split the beams in the x-axis direction and then split them in the y-axis direction, and conversely, the y-axis beam splitting optical system and the x-axis beam splitting optical system may be sequentially disposed to first split the beams in the y-axis direction and then split them in the x-axis direction.

The two-dimensional diffractive optical element DOE may split light into “m” beams in the x-direction and “n” beams in the y-direction. The splitting of the beams may be performed temporally and/or spatially. The splitting in the x-direction and the splitting in the y-direction may be performed in different forms. In this case, the two-dimensional diffractive optical element DOE may independently or dependently split the beams along the x direction and the y direction.

The attenuator ATT may selectively change some properties of beams that exit the two-dimensional diffractive optical element DOE. The attenuator ATT may change the power, amplitude, transmittance, and/or the like of the beams that exit the two-dimensional diffractive optical element DOE in the x-axis direction and the y-axis direction. For example, the attenuator ATT may sequentially decrease or increase the intensity of the individual beam depending on the scan direction, and if needed, may selectively adjust a degree of decrease or increase. In an embodiment, the attenuator ATT may set the transmittance of the beams in the x-axis direction and the y-axis direction differently depending on their positions in space, and for example, may selectively change the transmittance on the y axis.

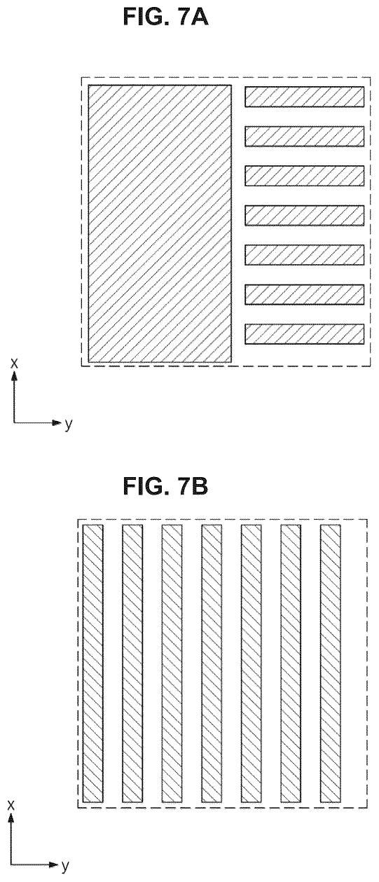

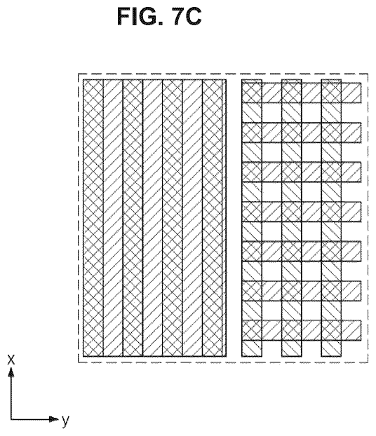

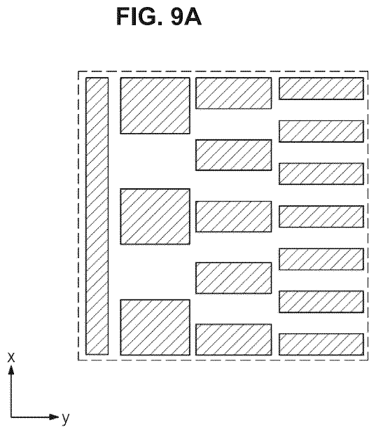

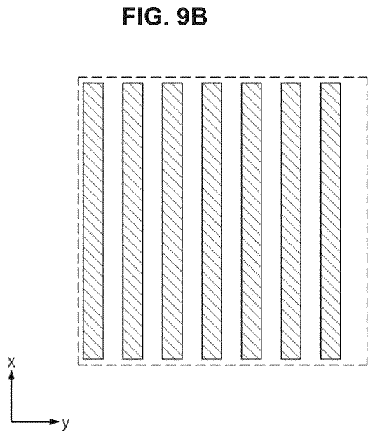

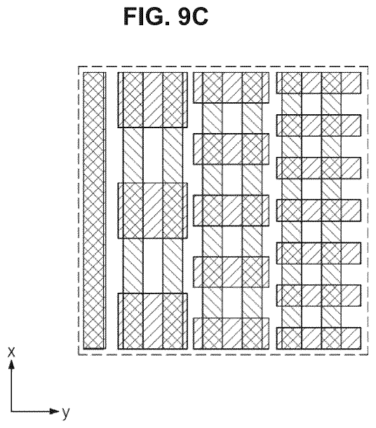

In an embodiment, the two-dimensional beam splitting optical system including the two-dimensional diffractive optical element DOE and/or the attenuator ATT may be a passive element. The two-dimensional beam splitting optical system and/or the attenuator ATT may be fixed through a predetermined setting, and may be replaced with other elements when different operations are required. For example, the laser cutting apparatus may include a two-dimensional beam splitting optical system corresponding to FIGS. 7A to 7C that will be described later, and may be replaced with a two-dimensional beam splitting optical system corresponding to FIGS. 9A to 9C when more splitting in the x direction is required.

Similarly, the attenuator ATT may be fixed through a specific setting or replaced with one having a different setting. The replacement of the two-dimensional beam splitting optical system and/or the attenuator ATT may be automatically performed (e.g., by a user's selection). However, the present disclosure is not limited thereto, and a manual replacement may also be possible. However, the present disclosure is not limited thereto, and when the two-dimensional beam splitting optical system and/or the attenuator ATT are coupled to an active element and are provided as an active assembly, a separate replacement may not be required.

FIGS. 7A to 7C are schematic views illustrating the splitting of beams using the two-dimensional beam splitting optical system according to an embodiment, wherein FIG. 7A is a schematic view illustrating an optical refraction pattern in the x-axis direction, FIG. 7B is a schematic view illustrating an optical refraction pattern in the y-axis direction, and FIG. 7C is a schematic view illustrating optical refraction patterns in the x-axis and y-axis directions simultaneously. In FIG. 7C, the beams that are refracted by the optical refraction pattern in the x-axis direction and/or the y-axis direction to be split are irradiated onto the wafer WF corresponding to an overlapping portion. Here, the beams refracted by the optical refraction pattern are intentionally illustrated to be spaced apart from each other to indicate a spatial separation therebetween, and the sizes of the beams and the spacing between the beams do not completely match the sizes of the beams and the spacing between the beams.

Referring to FIGS. 7A to 7C, the light that exits the light source may be split into a plurality of beams as the light is refracted along the x axis and the y axis, respectively. Here, a degree of splitting along the x-axis direction may be different from a degree of splitting in the y-axis direction. For example, the splitting in the y-axis direction may be splitting into a total of seven beams, and the split beams may be regularly arranged at a specific spacing spatially. On the other hand, the splitting along the x-axis direction may be splitting into a plurality of beams (for example, seven beams) at a portion that is placed ahead in the scan direction (e.g., portion that is closer to a head of the arrow indicating the scan direction), but may not be split and may maintain one beam at a portion that is placed behind in the scan direction (e.g., portion that is closer to a tail of the arrow). In this case, light may be split along the x-axis direction in some sections on the y axis along the scan direction. For example, each beam may be split into seven beams along the x axis in some sections on the y axis. In this way, the number of the beams split in the x direction may vary along the y-axis direction. The beams split in the x-axis direction may or may not overlap each other along the x axis.

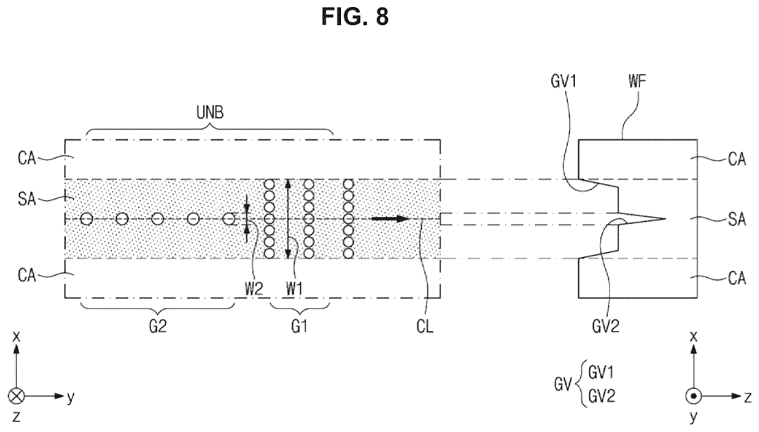

FIG. 8 illustrates an etching state of a wafer WF when the beams of FIG. 7C are irradiated onto the wafer WF together.

Referring to FIG. 8, the beams that exit the laser cutting apparatus may be output onto the wafer WF along the scan direction.

Each unit beam UNB that exits a processing device for the wafer WF may include a plurality of beams that are modulated by a two-dimensional beam splitting optical system. As illustrated in FIG. 8, each unit beam may include the beams G1 of the first group split in the y-axis direction and the beams G2 of the second group split in both the x-axis and y-axis directions. The beams G1 of the first group may be placed ahead along the scan direction and the beams G2 of the second group may be placed behind along the scan direction.

The beams G2 of the second group may be provided in a spot form because the beams G2 undergo only y-axis splitting with no x-axis splitting. The beams G1 of the first group may be split in the x-axis direction such that a plurality of beams are provided in a spot form, and may be arranged in the x-axis direction. Accordingly, a total sum of the widths of the respective split beams may be the width of the beams G1 of the first group. Here, when the width of the beams G1 of the first group in the x direction is assumed to be the first width W1, and a total sum of the x direction widths of the beams G2 of the second group is assumed to be the second width W2, the first width W1 may be greater than the second width W2.

When the beams are irradiated onto the wafer WF along the y direction, the wafer WF may be etched by the beams. The wafer WF may be etched in a depth direction from a surface of the wafer WF. The depth direction from the surface of the wafer WF may correspond to the z direction (or the z-axis direction) that is perpendicular to the x direction and the y direction.

The beams G1 of the first group may be placed ahead along the scan direction, and thus, a first groove GV1 corresponding to the width of the beams G1 of the first group may be formed on the wafer WF. Next, the beams G2 of the second group may be irradiated along the scan direction, and a second groove GV2 corresponding to the width of the beams G2 of the second group may be formed on the wafer WF. The first groove GV1 and the second groove GV2 may be formed to have sizes corresponding to the first width W1 and the second width W2, respectively.

Here, because the beams G1 of the first group are provided first and then the beams G2 of the second group are provided, the first groove GV1 may be formed first in the wafer WF and then the second groove GV2 may be formed within the first groove GV1.

Although not illustrated, in an embodiment, the forms of some of the beams refracted and split by the two-dimensional beam splitting optical system may be modulated. For example, some of the beams that are placed ahead, among the beams split along the y axis, may be modulated into a flat top shape by the flat top modulator FTM, and/or the like. For example, at least some of the beams G1 of the first group may also be modulated into a flat top form.

FIGS. 9A to 9C are schematic views illustrating the splitting of beams using the two-dimensional beam splitting optical system according to an embodiment, wherein FIG. 9A is a schematic view illustrating an optical refraction pattern in the x-axis direction, FIG. 9B is a schematic view illustrating an optical refraction pattern in the y-axis direction, and FIG. 9C is a schematic view illustrating optical refraction patterns in the x-axis and y-axis directions simultaneously. In FIG. 9C, the beams that are split by the optical refraction pattern in the x-axis direction and/or the y-axis direction are irradiated onto the wafer WF corresponding to an overlapping portion.

Referring to FIGS. 9A to 9C, when light that exits the light source LG along the x axis is split into a plurality of beams, the splitting may occur a plurality of times. For example, the number of the beams split in the x direction may be gradually changed along the y direction.

Here, the degree of splitting along the x-axis direction may be different from the degree of splitting in the y-axis direction, and the beams split in the y-axis direction may be regularly arranged at a specific spacing spatially. On the other hand, the splitting along the x-axis direction may be splitting into a plurality of beams in multiple stages at a portion that is placed ahead in the scan direction. In this case, primary splitting may be performed in some sections on the y axis along the scan direction, secondary splitting may be performed in some other sections on the y axis, and tertiary splitting may be performed in some other section on the y axis. The number of the beams split in the x direction may vary along the y-axis direction. The beams split in the x-axis direction may or may not overlap each other along the x axis.

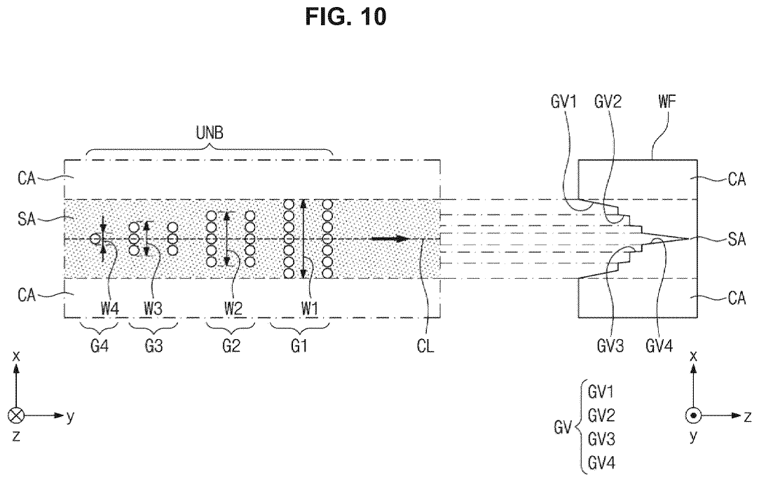

FIG. 10 illustrates the beams of FIG. 9C, and illustrates an etching state of a wafer WF when the beams of FIG. 9C are irradiated onto the wafer WF together.

Referring to FIG. 10, the beams that exit the laser cutting apparatus may be output onto the wafer WF along the scan direction. Each unit beam that exits a processing device for the wafer WF may include a plurality of beams that are modulated by a two-dimensional beam splitting optical system.

As illustrated in FIGS. 9C and 10 by way of example, each unit beam may include beams G4 of a fourth group that are split only in the y-axis direction, beams G3 of a third group that are split primarily in the x-axis direction in addition to the splitting in the y-axis direction, the beams G2 of the second group that are split secondarily in the x-axis direction in addition to the splitting in the y-axis direction, and the beams G1 of the first group that are split tertiarily in the x-axis direction in addition to the splitting in the y-axis direction. One light may be split into three beams arranged in the x-axis direction through the primary splitting in the x-axis direction, one light may be split into fourth beams arranged in the x-axis direction through the secondary splitting in the x-axis direction, and one light may be split into seven beams arranged in the x-axis direction through the tertiary splitting in the x-axis direction.

The split beams may be irradiated onto the wafer WF along the scan direction, and the beams G1 of the first group may be placed ahead, and the beams G2 of the second group G2, the beams G3 of the third group, and the beams G4 of the fourth group may be placed behind in that order. The beams G4 of the fourth group may be provided in a spot form because the beams G4 undergo only y-axis splitting with no x-axis splitting. The beams G1-G3 of the first to third groups may be split in the x-axis direction in addition to the splitting in the y-axis direction, such that a plurality of beams may be provided in a spot form and may be arranged in the x-axis direction. Accordingly, a total sum of the widths of the respective split beams may be the width of the beams of each group. Here, when the x direction width of the beams G1 of the first group is assumed to be a first width W1, and the x direction widths of the beams G2-G4 of the second to fourth groups are assumed to be second to fourth widths W2 to W4, the first to fourth widths W1 to W4 may have sequentially smaller values.

When the beams are irradiated onto the wafer WF along the y direction, the wafer WF may be etched by the beams. The wafer WF may be etched in a depth direction from a surface of the wafer WF. The depth direction from the surface of the wafer WF may correspond to the z direction (or the z-axis direction) that is perpendicular to the x direction and the y direction.

Because the beams G1, G2, G3, and G4 of the first, second, third, and fourth groups are sequentially placed ahead along the scan direction, grooves GV having widths corresponding to the widths of the beams of each group may be formed on the wafer WF. Here, the grooves GV formed by etching by the beams G1, G2, G3, and G4 of the first to fourth groups are assumed to be first to fourth grooves GV1 to GV4, and the first to fourth grooves GV1 to GV4 may be formed with sizes corresponding to the first to fourth widths W1 to W4, respectively.

Although not illustrated, in an embodiment, the forms of some of the beams split by the two-dimensional beam splitting optical system may be modulated. For example, some of the beams that are placed ahead, among the beams split along the y axis, may be modulated into a flat top shape by the flat top modulator FTM, and/or the like. For example, at least some of the beams G2 of the second group may also be modulated into a flat top form.

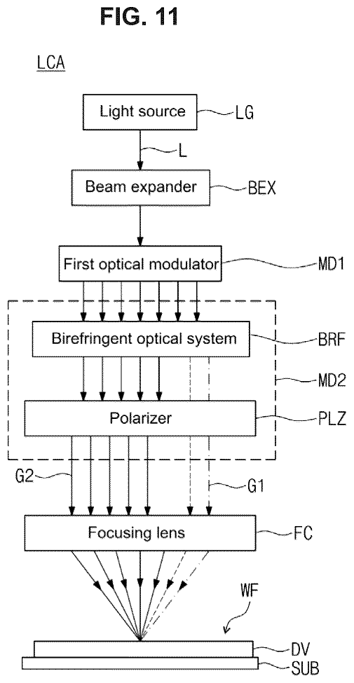

FIG. 11 is a block diagram illustrating a laser cutting apparatus LCA according to an embodiment of the present disclosure.

Referring to FIG. 11, a laser cutting apparatus LCA may include a light source LG, a beam expander BEX, a first optical modulator MD1, a second optical modulator MD2, and a focusing lens FC. In an embodiment, the second optical modulator MD2 may include a birefringent optical system BRF and a polarizer PLZ. The focusing lens FC may be a birefringent lens that concentrates birefringed beams.

The birefringent optical system BRF may include a component (e.g., a birefringent lens, and/or the like) having optical anisotropy. The birefringent optical system BRF may have different refractive indexes depending on a polarization direction of light, and a refractive index in a direction that is perpendicular to an optical axis and a refractive index in a direction that is parallel to the optical axis may be different from each other. Accordingly, the beams that have passed through the birefringent optical system BRF may be divided into beams in a direction that is perpendicular to the optical axis and beams in a direction that is parallel to the optical axis. When the beams that are perpendicular to the optical axis are assumed to be the beams G1 of the first group and the beams that are parallel to the optical axis are assumed to be the beams G2 of the second group, the beams G1 of the first group may correspond to ordinary rays, and the beams G2 of the second group may correspond to extraordinary rays.

The polarizer PLZ may polarize at least a portion of the two beams, i.e., the first and second groups of beams G1 and G2 that are separated by the birefringent optical system BRF at different degrees.

In an embodiment, the polarizer PLZ may modulate the beams G1 and G2 of the first and second groups that exit the birefringent optical system BRF such that power ratios of the polarization components are different. For example, the polarizer PLZ may modulate the beams G1 and G2 of the first and second groups such that the power ratios of the x-axis polarization component and the y-axis polarization component are different. In an embodiment, the beams G1 of the first group may have a ratio of the x-axis polarization component that is greater than the y axis polarization component, and the beams G2 of the second group may have a ratio of the x axis polarization component that is smaller than the y-axis polarization component.

In another embodiment, the polarizer PLZ may polarize at least a portion of the light that exits the birefringent optical system BRF at a specific angle. For example, the polarizer PLZ may polarize the light into light that vibrates mainly in the x-axis direction, or may polarize the light into light that vibrate mainly in the y-axis direction. In an embodiment, some of the light of the first group G1 may be polarized in the x-axis direction and the remaining portions thereof may be polarized in the y-axis direction. Alternatively, the polarizer PLZ may polarize some of the lights of the second group G2 in the x-axis direction and the remaining ones may be polarized in the y-axis direction. In an embodiment, the polarizer PLZ may adjust a degree of polarization in the x-axis direction and/or a ratio of the polarized light in the y-axis direction.

Although not illustrated, the laser cutting apparatus LCA may further include an attenuator that selectively changes some properties of the beams that exit the polarizer PLZ. The attenuator may change the power, amplitude, transmittance, and/or the like of the beams that exit the polarizer PLZ in the x-axis direction and the y-axis direction.

The lights polarized in different directions may be irradiated onto the wafer WF to etch the wafer WF at different degrees.

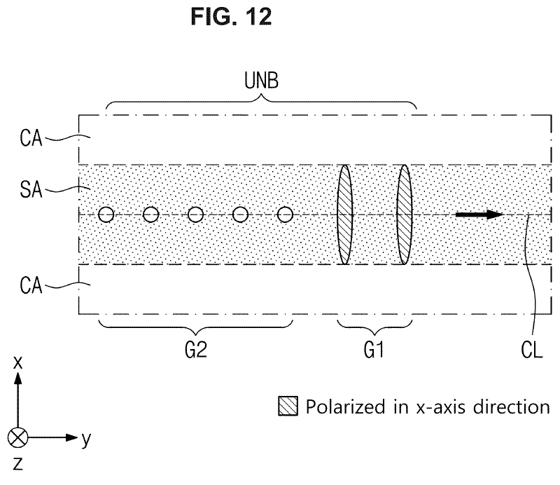

FIG. 12 illustrates one of the beams of the laser cutting apparatus of FIG. 11.

Referring to FIG. 12, the beams G1, G2 of the first group and the second group may be divided by the birefringent optical system BRF. The polarizer PLZ may polarize the beams G1 of the first group in a specific direction, for example, in the x-axis direction as illustrated. The beams polarized in a specific direction may be applied to the wafer WF to implement etching in a specific direction. However, the polarization direction may not be identical to the etching direction.

The beams G1 of the first group polarized in a specific direction (e.g., the x direction) may etch the wafer WF in a specific direction (e.g., the x direction) compared to the beams G2 of the second group that are not polarized. Accordingly, a width etched by the beams G1 of the first group may be greater than a width etched by the beams G2 of the second group.

The laser cutting apparatus according to the above-described embodiment and the components constituting each laser cutting apparatus may be combined in various forms, except in cases, in which they are incompatible with each other. For example, when a component such as an attenuator or a delay line system is not illustrated in the laser cutting apparatus, the component is not excluded and may be combined in various forms.

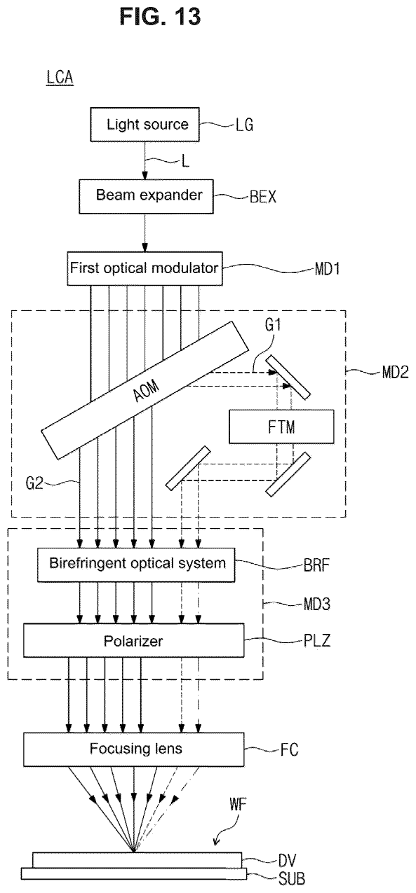

FIG. 13 is a block diagram illustrating a laser cutting apparatus LCA according to an embodiment of the present disclosure.

Referring to FIG. 13, the laser cutting apparatus LCA may include a light source LG, a beam expander BEX, a first optical modulator MD1, a second optical modulator MD2, and a third optical modulator MD3. The second optical modulator MD2 may include an acousto-optic modulator AOM and a flat top modulator FTM, and the third optical modulator MD3 may include a birefringent optical system BRF and a polarizer PLZ.

The first optical modulator MD1 may be a beam splitting optical system that splits the laser beam “L” that exits the light source LG into a plurality of beams. The first optical modulator MD1 may split the exiting laser beam “L” into the plurality of beams along the scan direction of the laser. When a direction, in which the laser beam “L” is scanned, is assumed to be the y-axis direction and a direction that is perpendicular to the scan direction is assumed to be the x-axis direction, the first optical modulator MD1, for example, may split the laser beam “L” into a plurality of beams that is split along the y axis.

The beams split in the first optical modulator MD1 may be modulated into beams having a plurality of different optical axes in the acousto-optic modulator AOM of the second optical modulator MD2. The acousto-optic modulator AOM may change the amplitude, frequency, phase, polarization, spatial position, and/or optical axis of the split beams by using the diffraction effect of light. The acousto-optic modulator AOM may cause the beams G1 of the first group and the beams G2 of the second group to be deflected with different optical axes. Accordingly, the deflected first group of beams G1 and the beams G2 of the second group may travel in different paths.

A flat top modulator FTM may be provided on the path of the beams G1 of the first group. The flat top modulator FTM may modulate the waveform of the beams G1 of the first group. In an embodiment, the flat top modulator FTM may modulate the beams G1 of the first group into flat top light instead of Gaussian form.

The beams G1 and G2 of the first and second groups that exit the flat top modulator FTM may propagate to the third optical modulator MD3.

The beams G1 and G2 of the first and second groups may be split into a plurality of beams by the birefringent optical system BRF, respectively. The polarizer PLZ may polarize the beams that have passed through the birefringent optical system BRF. For example, the polarizer PLZ may polarize the beams to split them into beams polarized in the x-axis direction and beams polarized in the y-axis direction.

The beams that exit the polarizer PLZ pass through the focusing lens FC and are irradiated onto the wafer WF, such that the wafer WF may be etched at different degrees.

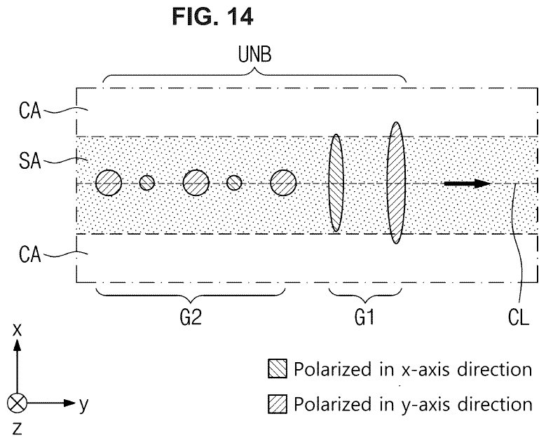

FIG. 14 illustrates one of the beams exiting the laser cutting apparatus LCA of FIG. 13.

Referring to FIGS. 13 and 14, the beams G1 of the first group and the beams G2 of the second group may be modulated into lights having different waveforms by the acousto-optic modulator AOM and the flat top modulator FTM. The beams G2 of the second group may have a Gaussian form and the beams G1 of the first group may have a flat top form. The birefringent optical system BRF and the polarization system may modulate the light polarized in the x axis or y axis to have different intensities, amplitudes, and/or the like while polarizing the beams G1 of the first group and the beams G2 of the second group in the x axis or y-axis direction, respectively.

In an embodiment, the beams polarized in the x axis or the y axis may be disposed alternately, and they may have different intensities and amplitudes. For example, the beams polarized in the y axis may have greater intensities and/or amplitudes than those of the beams polarized along the x axis. In order to illustrate this, in FIG. 14, a shape and an area of a spot for the beams polarized along the y axis are illustrated to be larger than those for the beams polarized along the x axis.

In an embodiment, in addition to the beams G1 of the first group and the beams G2 of the second group modulated to have different widths, by differently setting the properties of the polarization components of each beam, the wafer may be cut by varying an etching degree depending on a type of an etching target. For example, during a main processing that requires a relatively high intensity, polarized beams having relatively greater intensity and/or amplitude may be used, and during an auxiliary processing, polarized beams having relatively smaller intensity and/or amplitude may be used. In an embodiment, the main processing may include a process of etching at least a portion of an element layer or a substrate layer of the wafer, and the auxiliary processing may include a process of removing foreign substances, damaged areas, and/or the like that exist before or after the main processing. The auxiliary processing, for example, may include a process of removing debris and/or a heat affected zone HAZ generated during the process of removing the element layer and/or the substrate layer of the wafer.

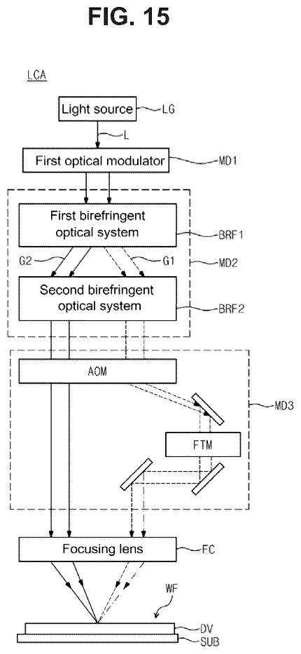

FIG. 15 is a block diagram illustrating a laser cutting apparatus LCA according to an embodiment of the present disclosure.

Referring to FIG. 13, a laser cutting apparatus LCA may include a light source LG, a first optical modulator MD1, a second optical modulator MD2, and a third optical modulator MD3. The second optical modulator MD2 may include first and second birefringent optical systems BRF1 and BRF2. The third optical modulator MD2 may include an acousto-optic modulator AOM and a flat top modulator FTM.

The first optical modulator MD1 may be a beam splitting optical system that splits the laser beam “L” that exits the light source LG into a plurality of beams. The first optical modulator MD1 may split the exiting laser beam “L” into the plurality of beams spatially spaced apart from each other along the scan direction of the laser. When a direction, in which the laser beam “L” is scanned, is assumed to be the y-axis direction and a direction that is perpendicular to the scan direction is assumed to be the x-axis direction, the first optical modulator MD1, for example, may split the laser beam “L” into a plurality of beams that is split along the y axis. For convenience of description, FIG. 15 illustrates that the first optical modulator MD1 splits the laser beam into two beams.

The beams split in the first optical modulator MD1 may be modulated into a plurality of spatially and/or temporally separated beams through the birefringent optical systems of the second optical modulator MD2.

The birefringent optical systems may include a first birefringent optical system BRF1 for secondarily spatially splitting the beams that have been primarily split in the first optical modulator MD1, and a second birefringent optical system BRF2 for temporally splitting the secondarily split beams.

The first birefringent optical system BRF1 may spatially space the split beams apart from each other along the optical axes of the beams that propagate through the birefringent optical system. In an embodiment, the first birefringent optical system BRF1 may modulate at least some of the beams that propagate in an interior thereof into the beams G1 of the first group and the beams G2 of the second group that are spatially separated, by polarizing them in a specific direction.

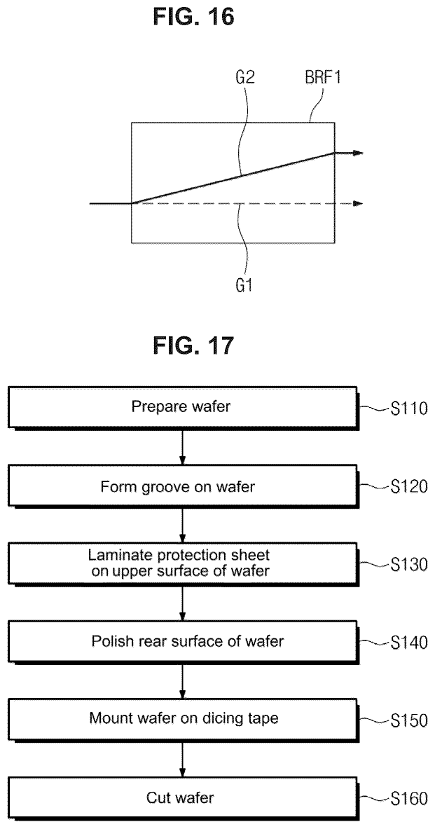

FIG. 16 is a schematic view illustrating secondary splitting of some of the beams split by a first birefringent optical system BRF1 of the present disclosure.

Referring to FIG. 16, the first birefringent optical system BRF1 may include an anisotropic material, for example, a birefringent crystal that polarizes beams in different optical-axis directions. For example, when the optical axis of the birefringent crystal in the first birefringent optical system BRF1 and the optical axes of the beams that propagate into the first birefringent optical system BRF1 are set to 10 to 80 degrees, the beams that propagate into the first birefringent optical system BRF1 may be split into the beams G1 of the first group polarized in the x-axis direction and the beams G2 of the second group polarized in the y-axis direction.

Referring again to FIG. 15, the second birefringent optical system BRF2 may change propagation speeds of the beams depending on the polarization direction and the optical axis of the beams that propagate in an interior thereof. This allows any one of the beams G1 of the first group and the beams G2 of the second group to be delayed in time relative to the other. In an embodiment, the second birefringent optical system BRF2 may include a uniaxial crystal having one optical axis. The propagation speeds of the beams that are perpendicular to the optical axis of the second birefringent optical system BRF2 and the beams that are parallel to the optical axis may be different in the uniaxial crystal. For example, when the optical axis of the crystal in the second birefringent optical system BRF2 and the optical axes of the beams that propagate into the second birefringent optical system BRF2 are set at 90 degrees, the polarization directions of the split beams, for example, the beams G1 of the first group polarized in the y-axis direction may propagate slower than the beams G2 of the second group polarized in the x-axis direction. Accordingly, the beams G1 of the first group polarized in the y-axis direction may have a temporally delayed waveform compared to the beams G2 of the second group polarized in the x-axis direction. In this way, the second birefringent optical system BRF2 may practically act as a phase retardation plate for the beams that pass through the second birefringent optical system BRF2.

The beams temporally/spatially split in the second optical modulator MD2 may be modulated into beams having a plurality of different paths in the acousto-optic modulator AOM of the third optical modulator MD3. The acousto-optic modulator AOM may change the amplitude, frequency, phase, polarization, spatial position, and/or optical axis of the split beams by using the diffraction effect of light, and in an embodiment, the spatial position may be changed. Accordingly, the deflected beams G1 of the first group and the deflected beams G2 of the second group may be positionally separated from each other and may propagate in different paths.

A flat top modulator FTM may be provided on the path of the beams G1 of the first group. The flat top modulator FTM may modulate the waveform of the beams G1 of the first group. In an embodiment, the flat top modulator FTM may modulate the beams G1 of the first group into flat top light instead of Gaussian form.

The beams G1 and G2 of the first and second groups that exit the flat top modulator FTM pass through the focusing lens FC and are irradiated onto the wafer WF to etch the wafer WF at different degrees.

The laser cutting apparatus having the above-described configuration may be driven in various ways, particularly in various irradiation modes of laser beams.

In the following description, for convenience of description, beams having the same properties are grouped and described as lights denoted by the same number. For example, the beams of the first group in FIG. 4 have substantially the same properties and will be described as a first light, and the beams of the second group have substantially the same properties while being different from the first light and will be described as a second light. Lights denoted by different numbers are lights with different properties. For example, in FIG. 10, the beams of the first to fourth groups are sequentially assumed to be a first light, a second light, a third light, and a fourth light having different properties.

The irradiation modes of the laser cutting apparatus may include a first mode of sequentially irradiating different lights and/or a second mode of simultaneously irradiating at least some of the different lights.

At least one of the first and second modes may be implemented by one laser cutting apparatus or may be implemented by a plurality of laser cutting apparatuses. When at least any one of the first and second modes is performed by the plurality of laser cutting apparatuses, an individual laser cutting apparatus may implement only one of the first and second modes.

In an embodiment, the user may select which of the first and second modes to proceed with. The user may select a manual irradiation mode or an automatic irradiation mode. When the automatic irradiation mode is selected, the irradiation mode may be selected according to an automated manual for specific conditions.

The first mode may be a mode in which irradiation of a light that is placed ahead, among “n” lights, is completed, and then irradiation of a light that is placed behind is sequentially performed. For example, in the first mode, irradiation of the second light may be sequentially performed after the irradiation of the first light is completed. Here, the first mode may be performed in a plurality of scans, and one light may be provided per scan. That is, one of the “n” lights may be irradiated in one scan.

The “n” lights may be irradiated a plurality of times. For example, the irradiation of the first light may be performed a plurality of times, and the irradiation of the second light may also be performed a plurality of times. In an embodiment, the irradiation of the first light and the irradiation of the second light may each be performed once. In another embodiment, the irradiation of the first light and the irradiation of the second light may each be performed a plurality of times, and the irradiation of the first light and the irradiation of the second light may be performed alternately. Alternatively, the second light may be irradiated a plurality of times after the first light is irradiated a plurality of times.

The second mode may be a mode, in which “n” lights are irradiated in one scan. That is, in the second mode, the irradiation of the first light and the irradiation of the second light may be included in one scan. The “n” lights may be included in one unit beam. For example, the first light and the second light may be irradiated substantially at the same time. In the second mode, the scan may be repeated a plurality of times.

Below, a method for manufacturing a semiconductor element using a laser cutting apparatus is described.

FIG. 17 is a flowchart illustrating a method for processing a semiconductor element according to an embodiment.

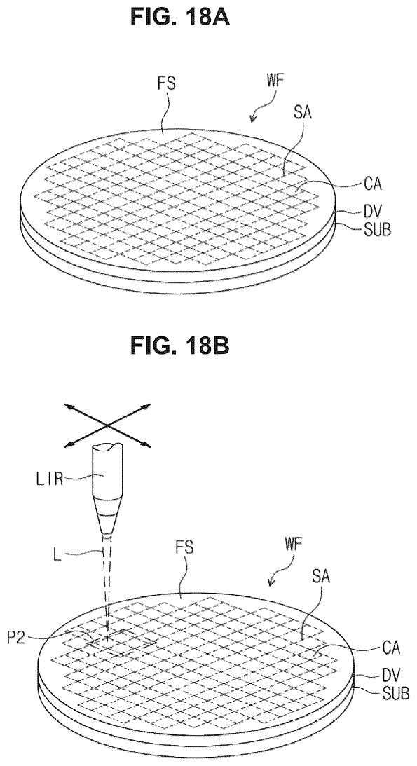

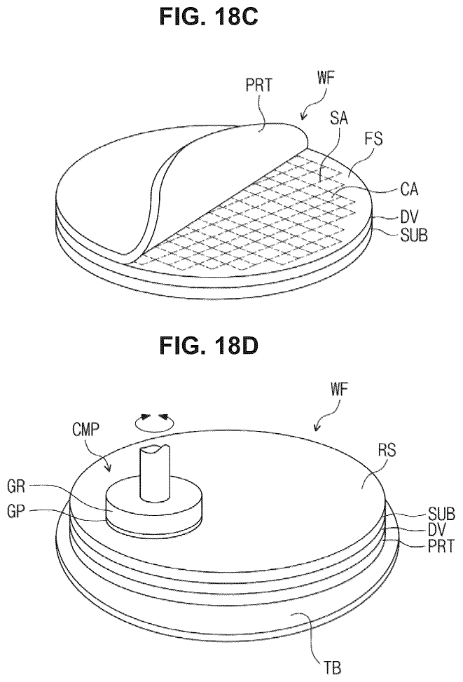

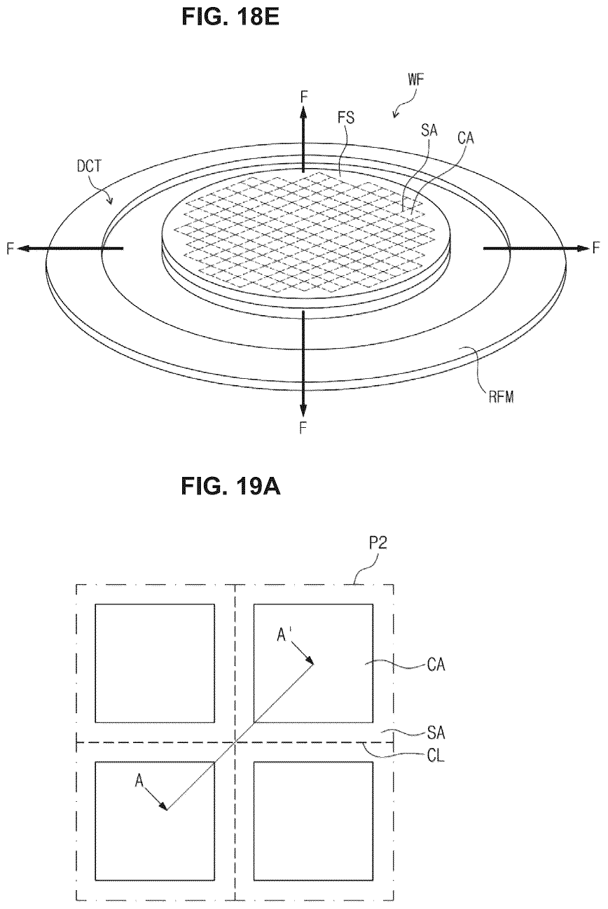

Referring to FIG. 17, according to an embodiment of the present disclosure, a semiconductor element may be manufactured by forming the wafer (S110), forming a groove on the wafer with a laser (S120), laminating a protection sheet PRT (refer to FIG. 18C) on an upper surface of the wafer, on which the groove has been formed (S130), polishing a rear surface of the wafer (S140), mounting the wafer on a dicing tape (S150), and then cutting the wafer by using the dicing tape (S160).

FIGS. 18A to 18E are schematic views sequentially illustrating a method for processing a semiconductor element.

Referring to FIGS. 17 and 18A, the wafer WF is formed. The wafer WF may include a substrate, and at least one element layer DV that is provided on the substrate. In FIGS. 18A to 18E, the element layer DV is illustrated as one layer for convenience of description, but the element layer DV may include various components.

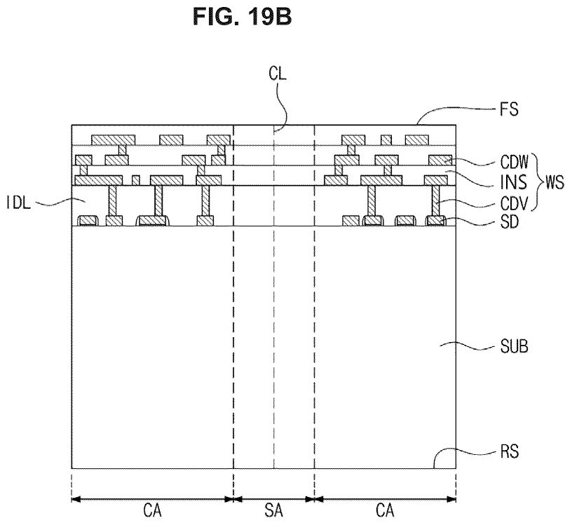

FIGS. 19A and 19B are views illustrating the wafer WF including the substrate and the element layer DV, and are an enlarged plan views of portion P2 of FIG. 18B, and FIG. 19B is a side cross-sectional view taken along line I-I′ of FIG. 19A.

Referring to FIGS. 18A, 19A, and 19B, the wafer WF may include a substrate layer SUB having a front surface and a rear surface that is opposite to the front surface, and the element layer DV that is disposed on the front surface of the substrate layer SUB.

The wafer WF may include a plurality of chip areas CA and a plurality of scribe lane areas SA. Here, the plurality of chip areas CA and the plurality of scribe lane areas SA may be extended to the substrate layer SUB and the element layer DV in a direction that is perpendicular to the front surface, respectively, and may also be used as terms to distinguish the wafer WF.

The substrate layer SUB may be a wafer having a circular shape with a constant thickness. In an embodiment, the substrate layer SUB may mean a substrate that is formed by a semiconductor material or a substrate that includes a semiconductor material, and/or a substrate that is used as a base for forming a semiconductor element even though the substrate does not include a semiconductor material. In an embodiment, the substrate layer SUB may be a silicon wafer. The substrate layer SUB is not limited thereto, and may be a wafer including a semiconductor element, such as germanium, or a compound, such as silicon carbide (SIC), gallium arsenide (GaAs), indium arsenide (InAs), and indium phosphide (InP). Alternatively, the substrate layer SUB may have a silicon on insulator (SOI) structure. In some embodiments, the substrate layer SUB may include a well that is doped with impurities corresponding to a conductive area, or a structure that is doped with impurities. Furthermore, the substrate layer SUB may have various element isolation structures, such as a shallow trench isolation (STI) structure.

The element layer DV may have a plurality of integrated circuit areas and may be formed on the front surface FS of the substrate layer SUB. The plurality of chip areas CA may be separated from each other and be provided as semiconductor chips together with the substrate layer SUB in a subsequent process.

The plurality of chip areas CA may include a plurality of semiconductor elements SD. The semiconductor elements SD may be divided into memory elements and logic elements.

The memory device may include a volatile memory element or a non-volatile memory element. For example, the volatile memory element may include a memory element such as, for example but not limited to, a dynamic random access memory (DRAM), a static RAM (SRAM), a thyristor RAM (TRAM), a zerocapacitor RAM (ZRAM), or a twin transistor RAM (TTRAM). Furthermore, the non-volatile memory element, for example, may include a memory element such as a flash memory, a magnetic RAM (MRAM), a spin-transfer torque MRAM (STT-MRAM), a ferroelectric RAM (FRAM), a phase change RAM (PRAM), a resistive RAM (RRAM), a nanotube RRAM, a polymer RAM, a nano floating gate memory, a holographic memory, a molecular electronics memory, or an insulator resistance change memory.

The logic element, for example, may be implemented by, for example but not limited to, a microprocessor, a graphics processor, a signal processor, a network processor, an audio codec, a video codec, an application processor, or a system on a chip, but the present disclosure is not limited thereto.

Each of the plurality of chip areas CA may be disposed to be isolated from each other by the plurality of scribe lane areas SA. The plurality of scribe lane areas SA may include an area, through which the cutting line CL passes. Here, the cutting line CL may be an imaginary line. In a dicing process that will be described later, the wafer WF may be cut along the cutting line CL. The scribe lane areas SA may be configured such that a portion that extends in a row direction and a portion that extends in a column direction cross each other. The scribe lane areas SA may be in a form of straight lanes having a constant width. As illustrated in FIG. 19A, the chip areas CA may be arranged in a plurality of rows and a plurality of columns with the scribe lane areas SA interposed therebetween. The chip areas CA may be disposed to be spaced apart from each other while each of the chip areas is surrounded by a corresponding scribe lane area SA.

Each of the plurality of chip areas CA may be an area, in which semiconductor elements SD for memory or logic functions are formed. The scribe lane area SA may be an area, in which the semiconductor elements are not formed. In some embodiments, a plurality of semiconductor dummy elements may be arranged in the scribe lane area(s) SA.

In an embodiment, the element layer DV may be configured to include an inter-layer insulation film IDL that is disposed on the front surface and covers the semiconductor elements SD, and a wiring structure WS that is disposed on the inter-layer insulation film IDL and is connected to the semiconductor elements SD. The wiring structure WS may have a multilayer wiring structure WS, in which insulating layers INS and conductive wirings CDW are alternately disposed. Furthermore, the conductive wiring CDW of each layer may include a plurality of conductive vias CDV that are disposed in a direction that is perpendicular to the front surface of the substrate layer SUB. For example, the conductive wirings CDW and the conductive vias CDV may be formed of a conductive material including at least one of, for example but not limited to, aluminum (Al), copper (Cu), nickel (Ni), tungsten, platinum (Pt), and gold (Au). In the embodiment, the multilayer conductive wirings CDW are illustrated as three layers, but the present disclosure not limited thereto. Unlike the embodiment, it may be formed of two layers or four or more layers.

The inter-layer insulation film IDL may be formed of a low-dielectric material. The low-dielectric material is a material having a lower dielectric constant than silicon oxide, and when used as the inter-layer insulation film IDL in the semiconductor element SD, it may be advantageous in realizing high integration and high speed of the semiconductor element SD due to an improved insulation ability. A dummy structure that is similar to the wiring structure WS may be formed in the scribe lane area SA. For example, the dummy structure disposed in the scribe lane area SA may include the inter-layer insulation film IDL and a plurality of layers of dummy wirings corresponding to the conductive wirings CDW and the inter-layer insulation film IDL. In some embodiments, the scribe lane area SA may include a test pattern for testing the semiconductor elements SD of the chip areas CA, a redistribution layer for connecting the test patterns, and/or an alignment key for aligning a mask. Furthermore, in some embodiments, a material film having various functions, such as a passivation film, may be additionally formed on the element layer DV.

A process of forming the semiconductor element SD may include an oxidation process for forming an oxide film, a lithography process including spin coating, exposure and development, a thin film deposition process, a dry or wet etching process, and a metal wiring process.

The oxidation process may be a process of forming a thin and uniform silicon oxide film by bringing oxygen or water vapor into a chemical reaction with a surface of a silicon substrate at a high temperature of about 800° C. to about 1200° C. The oxidation process may include dry oxidation and wet oxidation. In the dry oxidation, an oxide film may be formed through a reaction with oxygen gas, and in the wet oxidation, an oxide film may be formed through a reaction of oxygen and water vapor.

The lithography process is a process of transferring a circuit pattern formed in advance on a lithography mask to a substrate through exposure. The lithography process may be performed in the order of spin coating, exposure, and development processes.

The thin film deposition process may include, for example but not limited to, any one of atomic layer deposition (ALD), chemical vapor deposition (CVD), plasma-enhanced CVD (PECVD), metal organic CVD (MOCVD), physical vapor deposition (PVD), reactive pulsed laser deposition, molecular beam epitaxy, and direct current (DC) magnetron sputtering.

The dry etching process may include, for example but not limited to, any one of reactive ion etching (RIE), Deep RIE (DRIE), ion beam etching (IBE), and Ar milling. As another example, the dry etching process that may be performed on the wafer may be atomic layer etching (ALE). Furthermore, the dry etching process that may be performed on the wafer WF may use at least any one of Cl₂, HCl, CHF₃, CH₂F₂, CH₃F, H₂, BCL₃, SiCl₄, Br₂, HBr, NF₃, CF₄, C₂F₆, C₄F₈, SF₆, O₂, SO₂, and COS as an etchant gas.

The conductive wiring CDW process may be a process of forming a conductive wiring CDW (e.g., a metal wiring) to implement a circuit pattern for the operation of a semiconductor element SD. Through the conductive wiring CDW process, the ground, power, and signal transmission paths for operating the semiconductor element SD may be formed. The conductive wiring CDW may include a metal element such as, for example but not limited to, at least any one of Au, Pt, Ag, Cu, Al, Ti, Ta, and W.

In some embodiments, in the semiconductor element SD forming process, a planarization process, such as a chemical mechanical polishing CMP process or an etch-back process, or an ion implantation process, may also be performed.

Referring to FIGS. 17 and 18B, a plurality of grooves may be formed on the wafer WF. The grooves may be formed along the cutting line CL in the scribe lane area SA.

The operation of forming a plurality of grooves may be referred to as a dicing operation. The dicing operation may be an operation of removing only a portion of the wafer WF, and may also be referred to as a half dicing operation.

Through the plurality of grooves, laser beams may be irradiated onto the wafer WF by using the above-described laser cutting apparatus. However, the present disclosure is not limited thereto, and a laser beam may be irradiated on the wafer WF by using another laser cutting apparatus instead of the above-described laser cutting apparatus as long as it does not deviate from the concept of the present disclosure. In the drawing, only a portion of the laser cutting apparatus is disclosed for the convenience of description.

The laser cutting apparatus may irradiate a laser beam “L” from an upper surface toward a lower surface of the wafer WF. The laser beam “L” may be irradiated through a laser irradiation part LIR that is connected to the main body of the laser cutting apparatus LCA and irradiates the laser beam “L”.

The laser beam “L” irradiated by the laser cutting apparatus LCA may be selected from light having the following properties. In an embodiment, a wavelength band of the laser beam “L” may be about 100 nm to about 600 nm. In an embodiment, a pulse width of the laser beam “L” may be about 1 fs to 1000 ns, for example, about 1 fs to about 20 ps. In an embodiment, an energy per pulse of the laser beam “L” may be about 0.1 uJ to about 50 uJ. In an embodiment, an accumulated energy per unit area of the laser beam “L” may be about 0.1 J/m2 to 1000 J/m2. A width of the laser beam “L” may be about 1 um to about 1000 um.

The laser irradiation part LIR may be moved along the cutting line in the scribe lane area SA of the wafer WF. For example, the laser irradiation part LIR may be moved in a horizontal direction (e.g., parallel to the front surface FS of the wafer WF) and a direction perpendicular to the horizontal direction such that the laser beam “L” may be irradiated along the scribe lane area SA. Alternatively, the laser irradiation part LIR may be fixed and a stage, on which the wafer WF is mounted, may be moved such that the laser beam “L” is irradiated onto the scribe lane area SA. Furthermore, the laser irradiation part LIR and the stage, on which the wafer WF is mounted, may be moved simultaneously such that the laser beam “L” is irradiated onto the scribe lane area SA.

A corresponding area of the wafer WF may be removed by the laser beam “L” irradiated onto the wafer WF to form grooves. The grooves may be formed to pass through at least a portion of the wafer WF. The grooves may pass through at least a portion of the element layer DV, and may pass through a portion of the substrate layer SUB provided under the element layer DV.

The grooves may act as crack sites, at which cracks may occur due to external physical impacts.

In an embodiment, the process of irradiating a laser beam onto the wafer WF may be performed under various conditions depending on the wafer WF. This will be described later.

Referring to FIG. 17 and FIG. 18C, the protection sheet PRT may be laminated on the front surface of the wafer WF. The protection sheet PRT may prevent the surface of the wafer WF from being damaged in a subsequent process. For example, the protection sheet PRT may prevent foreign substances from being attached to an upper surface of the element layer DV.

Although not illustrated, the protection sheet PRT may include a polymer resin. The type of the polymer resin is not particularly limited. In an embodiment, the protection sheet PRT may be formed by forming and curing a thermosetting resin or by forming a thermoplastic resin. The protection sheet PRT may be formed by using a resin that may secure adhesion to the wafer WF, prevention of intrusion of foreign substances, and cleanability after cutting of a semiconductor wafer. As an example, the protection sheet PRT may include a fat-soluble resin or a water-soluble resin. The protection sheet PRT may be formed in various thicknesses as needed.

In an embodiment, the fat-soluble resin may include a polyurethane resin containing a urea group that is polymerized through a reaction of an alcohol or an amine with an isocyanate, or a thermoplastic resin, such as polystyrene (PS), polyethylene terephthalate (PET), or polypropylene (PP). The thermoplastic resin may have a molecular weight in a range of about 1000 Mw to 1,000,000 Mw. The water-soluble resin may include polyvinyl alcohol (PVA), polyvinyl pyrrolidone (PVP), or an ionic polymer having an ionic functional group.

Referring to FIG. 17 and FIG. 18D, a rear surface RS of the wafer WF may be polished. The rear surface of the wafer WF may be polished by using a polishing apparatus CMP.

The wafer WF, in which the protection sheet PRT is attached to an upper surface thereof, may be placed on a chuck table TB with the rear surface RS being inverted to face an upper side. The rear surface RS of the wafer WF may be a surface, on which the element layer DV is not formed, and may correspond to an inactive surface.

By polishing the rear surface RS of the wafer WF, a thickness of the substrate layer SUB in the wafer WF may be reduced.

The polishing apparatus CMP may include the chuck table TB that supports the substrate layer SUB, and a grinder GR that polishes the substrate layer SUB disposed on the chuck table TB. The grinder GR may be moved while being rotated, and a polishing pad GP may be attached to a lower portion of the grinder GR.

The polishing process may be a grinding process in a state in which a physical pressure is applied to the substrate layer SUB. The polished substrate layer SUB may have a smaller thickness than before being polished.

In an embodiment, cracks generated by the grooves may easily propagate through a process of polishing the rear surface RS of the wafer WF. In an embodiment, at least some of the cracks generated by the grooves may propagate toward the rear surface of the substrate layer SUB during the polishing process. However, the propagation of cracks generated by the grooves GV may not occur in the polishing operation for the wafer WF, but may occur in an expansion operation for the dicing tape that will be described later.

Referring to FIGS. 17 and 18E, the wafer WF may be mounted on a dicing tape DCT.

The wafer WF may be inverted again such that an upper surface (or front surface) of the wafer WF, to which the protect sheet PRT is attached, faces an upper side and be mounted on the dicing tape DCT. In an embodiment, the rear surface of the wafer WF may be attached onto the dicing tape DCT.

Although not illustrated separately, an adhesive film may be attached onto the rear surface of the wafer WF. The adhesive film may support the wafer WF, and may facilitate subsequent handling of the wafer WF. The adhesive film may be provided on the rear surface RS of the wafer WF before the wafer WF is attached onto the dicing tape DCT. In this case, the wafer WF may be attached onto the dicing tape DCT with the adhesive film interposed therebetween. Alternatively, the adhesive film may be attached to the rear surface of the wafer WF before grooves are formed on the wafer WF.

The protection sheet PRT may be removed after the wafer WF is mounted on the dicing tape DCT. The protection sheet PRT may be peeled off by a film peeler or removed through a wet cleaning process. The wet cleaning process may be performed by using an organic solvent or an inorganic solvent depending on a material of the protection sheet PRT.

The dicing tape DCT may be supported and fixed by a ring frame RFM that is attached to one surface thereof.

Next, an external force “F” may be applied to the dicing tape DCT to expand the dicing tape DCT such that individual semiconductor chips are divided from the wafer WF. The dicing tape DCT may be expanded radially as illustrated.

In an embodiment, the dicing tape DCT may be placed on a jig and the jig may be pushed upward to expand the dicing tape DCT.

By expanding the dicing tape DCT, the wafer WF may be cut into individual semiconductor chips along the scribe lane area SA. When the dicing tape DCT is expanded while the wafer WF is disposed on the dicing tape DCT, the substrate layer SUB may be subject to brittle fracture. Brittle fracture refers to destruction of an object without permanent deformation when a force of an elastic limit or more is applied to the object. The substrate layer SUB may be subject to brittle fracture by a crack CR that has propagated from an area, in which grooves are formed. The crack CR generated by the grooves may propagate toward the rear surface of the substrate layer SUB as the dicing tape DCT expands. Eventually, as the crack is formed along the scribe lane area SA that isolates the chip areas CA, the chip areas CA may be separated into individual semiconductor chips CHP due to the brittle fracture of the substrate layer SUB.

Although not illustrated, the individual semiconductor chips may be picked up by other process equipment and be transferred to a separate support substrate. The support substrate may be a temporary carrier that supports and fixes the semiconductor chips before the die attaching process.

According to an embodiment of the present disclosure, the process of cutting the wafer WF to manufacture semiconductor chips may be performed in a different order than the above-described order.

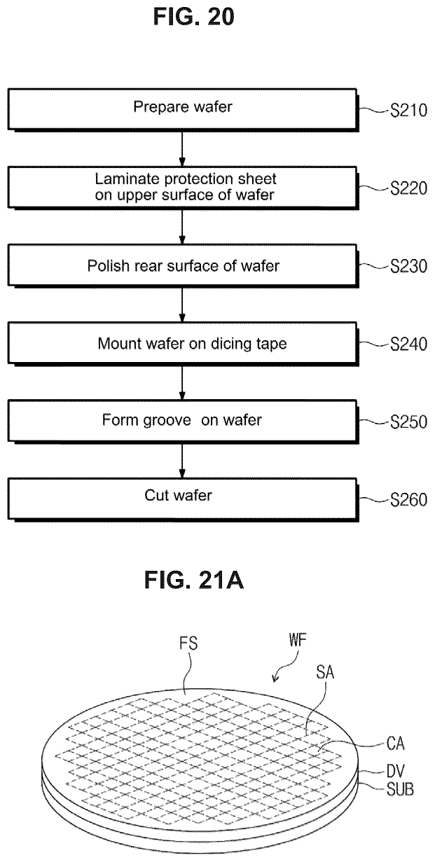

FIG. 20 is a flowchart illustrating a method for processing a semiconductor element according to an embodiment.

Referring to FIG. 20, according to an embodiment of the present disclosure, a semiconductor element may be manufactured by forming the wafer (S210), laminating a protection sheet on an upper surface of the wafer (S220), polishing a rear surface of the wafer (S230), mounting the wafer on a dicing tape (S240), forming a groove on the wafer with a laser (S250), and cutting the wafer having the groove by using the dicing tape (S260).

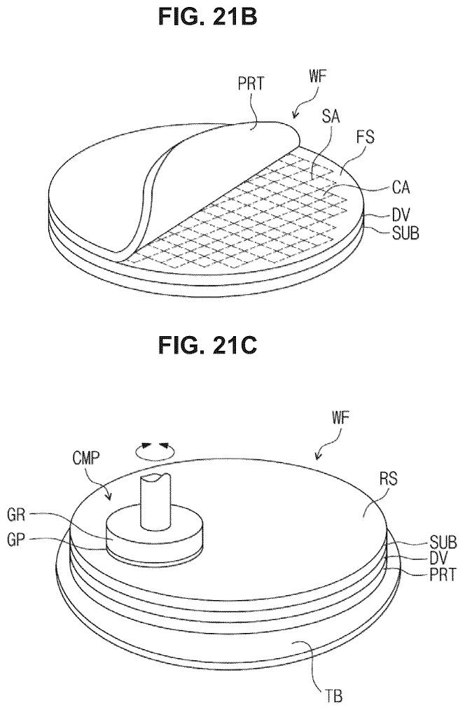

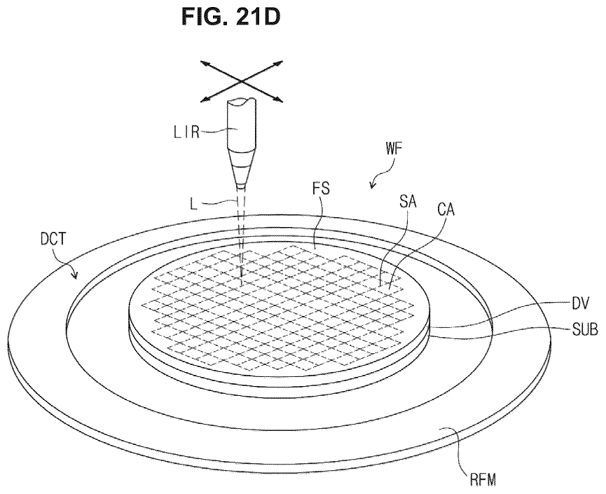

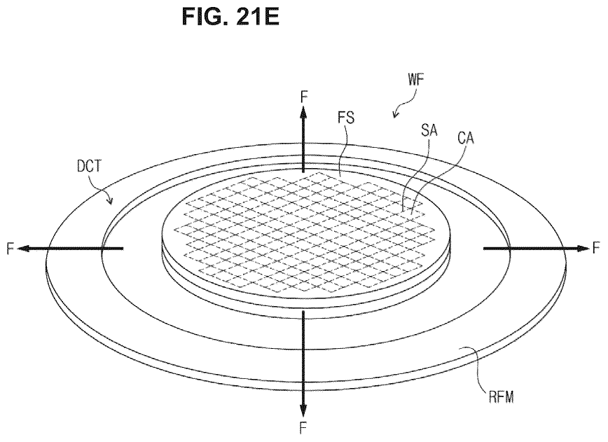

FIGS. 21A to 21E are schematic views sequentially illustrating a method for processing a semiconductor element.

Referring to FIGS. 20 and 21A, the wafer WF is formed. The wafer WF may include a substrate SUB, and at least one element layer DV that is provided on the substrate SUB.

Referring to FIG. 20 and FIG. 21B, a protection sheet PRT may be laminated on the front surface of the wafer WF. The protection sheet PRT may prevent the surface of the wafer WF from being damaged in a subsequent process.

Referring to FIG. 20 and FIG. 21C, a rear surface RS of the wafer WF may be polished. The rear surface RS of the wafer WF may be polished by using a polishing apparatus CMP. The wafer WF, to which the protection sheet PRT is attached, may be placed on a chuck table TB with the rear surface RS being inverted to face an upper side. The rear surface RS of the wafer WF may be a surface, on which an element layer DV is not formed, and may correspond to an inactive surface.

By polishing the rear surface RS of the wafer WF, the thickness of the substrate layer SUB in the wafer WF may be reduced.

Referring to FIGS. 20 and 21D, the wafer WF may be mounted on a dicing tape DCT.

The wafer WF may be inverted again such that an upper surface, to which the protect sheet PRT is attached, faces an upper side and be mounted on the dicing tape DCT. In an embodiment, the rear surface RS of the wafer WF may be attached onto the dicing tape DCT. The protection sheet PRT may be removed after the wafer WF is mounted on the dicing tape DCT.

Next, a plurality of grooves may be formed on the wafer WF. The grooves may be formed along the cutting line CL in the scribe lane area SA. Through the plurality of grooves, laser beams may be irradiated onto the wafer WF by using the above-described laser cutting apparatus. However, the present disclosure is not limited thereto, and a laser beam may be irradiated on the wafer WF by using another laser cutting apparatus instead of the above-described laser cutting apparatus as long as it does not deviate from the concept of the present disclosure.

Referring to FIGS. 20 and 21E, the dicing tape DCT may be expanded (S150 in FIG. 17) such that individual semiconductor chips are divided from the wafer WF. The dicing tape DCT may be expanded radially as illustrated.

In an embodiment, the dicing tape DCT may be placed on a jig and the jig may be pushed upward to expand the dicing tape DCT. When the dicing tape DCT is expanded, an external force “F” is applied to the wafer WF due to the expansion. A crack may occur in a downward direction from an apex of the groove formed in the substrate layer SUB due to the external force “F”. The adjacent semiconductor chips may be separated due to the crack, and eventually, the wafer WF may be cut into individual semiconductor chips along the scribe lane area SA due to the expansion of the dicing tape DCT. When the substrate layer SUB is formed of a crystal, the crack may occur along a specific plane in the crystal. An area of the substrate layer SUB cut by the crack, other than an area, in which the groove is formed, may have a cut surface that is substantially flat.

When the dicing tape DCT is expanded to apply a tension of the tape to the wafer WF, an expansion speed of the dicing tape DCT may be about 1 mm/s to about 1000 mm/s. For example, the expansion speed of the dicing tape DCT may be about 5 mm/s or more, or about 10 mm/s or more. An expansion length of the dicing tape DCT in one direction may be about 0.1 mm to about 100 mm, or about 0.1 mm to about 30 mm, for example, about 1 mm to about 20 mm.

The individual semiconductor chips may be picked up by other process equipment and be transferred to a separate support substrate. The support substrate may be a temporary carrier that supports and fixes the semiconductor chips before the die attaching process.

As described above, according to an embodiment of the present disclosure, laser beams may be irradiated by using the laser cutting apparatus either before or after mounting on the dicing tape DCT. Accordingly, in the method for cutting the wafer WF according to an embodiment of the present disclosure, the process order may be changed in various ways.

According to the related art, in the process of cutting the wafer by using a blade, the wafer may be cut only after mounting on the dicing tape, and thus, the order of the cutting process cannot be fixed. Furthermore, a stealth dicing method, in which a laser beam does not pass through the tape, is possible only before grinding, and thus, there are restrictions on the selection of the process order.′

For this reason, the method for cutting the wafer WF according to an embodiment of the present disclosure may be more advantageous in terms of management of raw material stagnation time, equipment layout, and logistics movement.

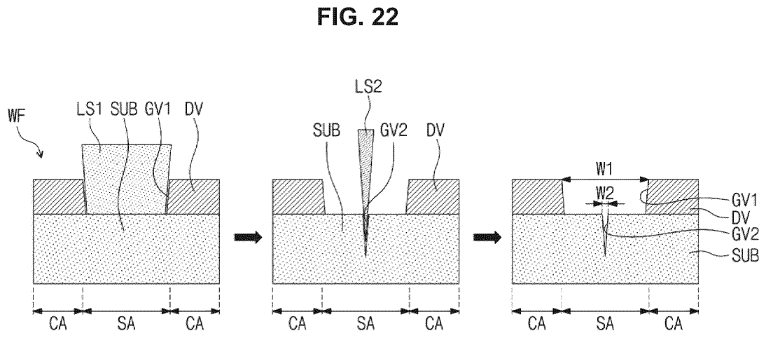

FIG. 22 is a schematic view illustrating operations of processing a wafer by using a laser. FIG. 22 may correspond to a case, in which the laser cutting apparatus is implemented in the first mode. Hereinafter, a “width” of light and a “width” of a groove GV in the drawing may correspond to a cross-sectional diameter of light at a position corresponding to a surface of a target object for convenience of description.

Referring to FIG. 22, lights having different properties may be sequentially irradiated onto the scribe lane area SA of the wafer WF. For example, in the first mode, irradiation of a second light LS2 may be sequentially performed after the irradiation of a first light LS1 is completed. In an embodiment, the lights having different properties may include, for example, the first light LS1 and the second light LS2.

The first light LS1 may be set as light that may etch the element layer DV. Considering a material that constitutes the element layer DV, a thickness of the element layer DV, and/or the like, variables such as power, pulse repetition rate, scan speed, focus position, width, shape of the light, number of branches of the light, wavelength, and/or position of the optical axis of the first light LS1 may be determined. For example, the first light LS1 may be light having a first width W1.

When the first light LS1 is irradiated onto the wafer WF, a portion of the wafer WF, for example, the element layer DV, may be etched by the first light LS1. A first groove GV1 may be formed on the wafer WF due to the etching of the element layer DV. An upper surface of the substrate layer SUB may be exposed by the first groove GV1. That is, a bottom surface of the first groove GV1 may correspond to the upper surface of the substrate layer SUB. The first groove GV1 may be formed to have a size corresponding to the width of the first light LS1.

In an embodiment, the bottom surface of the first groove GV1 may be flat. When the bottom surface of the first groove GV1 is not flat, scattering, reflection, refractive, and/or the like of the second light LS2 may occur due to the non-flat bottom surface of the first groove GV1 when the second light LS2 is irradiated, and accordingly, the second groove GV2 may be formed at an undesired point, and a shape of the second groove GV2 may also be different from an intended one.

After the first groove GV1 is formed by the first light LS1, the second light LS2 may be irradiated onto the wafer WF. The second light LS2 may be irradiated into the first groove GV1 formed by the first light LS1.

An irradiation angle of the first light LS1 may have a smaller value than an irradiation angle of the second light LS2 with respect to the upper surface of the wafer WF. When the irradiation angle of the first light LS1 is large, it may be difficult for the second light LS2 to efficiently propagate into the first groove GV1 due to an inclination of a side surface of the first groove GV1.

In an embodiment, the second light LS2 may be irradiated to a portion of a lower surface of the first groove GV1. In other words, when viewed on a plane, an area, in which the first light LS1 is provided, may be larger than an area, in which the second light LS2 is provided, and at least a portion of the area, in which the second light LS2 is provided, may overlap the area, in which the first light LS1 is provided. In an embodiment, the area, in which the second light LS2 is provided, may be provided within and to completely overlap the area, in which the first light LS1 is provided.

The second light LS2 may be set as light that may etch the substrate layer SUB. Considering the material that constitutes the substrate layer SUV, the thickness of the element layer DV, and/or the like, variables such as power, pulse repetition rate, scan speed, focus position, width, shape of the light, number of branches of the light, wavelength, and/or position of the optical axis of the second light LS2 may be determined. The second light LS2 may be light having different properties from those of the first light LS1, and at least one variable such as the power, pulse repetition rate, scan speed, focus position, width, shape of the light, number of branches of the light, wavelength, and/or position of the optical axis of the first light LS1 may be set differently.

In an embodiment, the second light LS2 may be light having a second width W2. The second width W2 may be smaller than the first width W1.

When the second light LS2 is irradiated onto the wafer WF, a portion of the wafer WF, for example, the substrate layer SUB, may be etched by the second light LS2. Due to the etching of the substrate layer SUB, the second groove GV2 may be formed in the substrate layer SUB. The second groove GV2 may have a depth from the upper surface of the substrate layer SUB toward the rear surface of the substrate layer SUB. The depth of the second groove GV2 may be smaller than the thickness of the substrate layer SUB. That is, the second groove GV2 may not pass through the substrate layer SUB, and the substrate layer SUB may be connected as an integral part without being separated in an area, in which the second groove GV2 is not formed. The second groove GV2 may have a shape, a width of which decreases from the upper surface to the rear surface of the substrate layer SUB. For example, the second groove GV2 may have a cone shape (or a “V” shape), an apex of which is located at a bottom thereof when viewed in a cross section. Alternatively, the second groove GV2 may have an “I” shape with a narrow width and a constant width. The second groove GV2, particularly, a lower end of the second groove GV2, may act as a crack site, at which cracks may occur due to an external physical impact.

In an embodiment, when the substrate layer SUB includes silicon and the element layer DV has an insulating layer INS including a low dielectric material, the intensity of the first light LS1 may be less than the intensity of the second light LS2.

The wafer WF may be partially cut (e.g., half-cut) by the first groove GV1 and the second groove GV2.

In an embodiment, the process of forming the first groove GV1 and the process of forming the second groove GV2 may be performed by using a single laser cutting apparatus. However, the present disclosure is not limited thereto, and the process of forming the first groove GV1 and the process of forming the second groove GV2 may be performed by using a plurality of laser cutting apparatuses. When a plurality of laser cutting apparatuses are used, the plurality of laser cutting apparatuses may be apparatuses having different specifications.

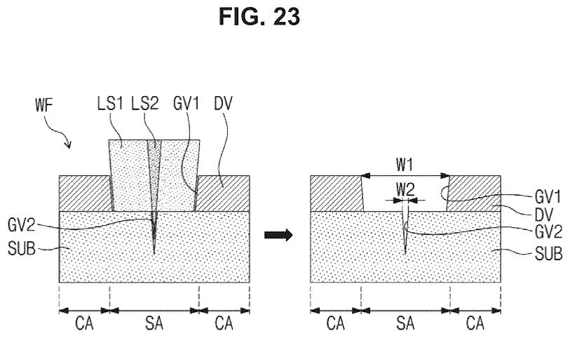

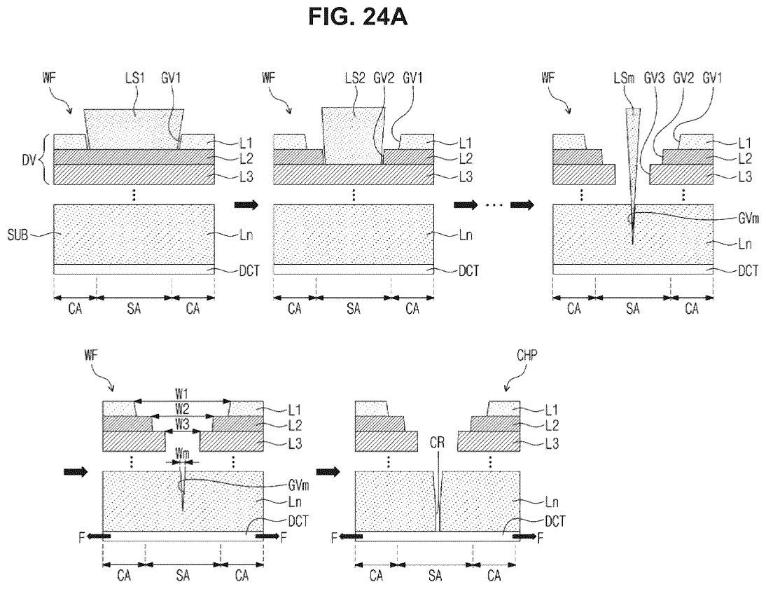

FIG. 23 is a schematic view illustrating operations of processing a wafer by using a laser. FIG. 22 may correspond to a case, in which the laser cutting apparatus is implemented in the second mode.

Referring to FIG. 23, lights having different properties may be irradiated together in one scan. For example, irradiation of the first light LS1 and the second light LS2 may be performed substantially simultaneously in each scan. However, the first light LS1 may be placed ahead of the second light LS2 in one scan.

The first light LS1 may be set as light that may etch the element layer DV, and the second light LS2 may be set as light that may etch the substrate layer SUB.

Here, the irradiation position, irradiation area, irradiation intensity, and/or the like of the first light LS1 and the second light LS2 may be controlled such that the second groove GV2 that is to be formed by the second light LS2 is disposed within the first groove GV1 that is to be formed by the first light LS1. In addition, variables such as the power of the light, the pulse repetition rate, the scan speed, the focus position, the width, the shape of the light, the number of splits of the light, the wavelength, the position of the optical axis, and/or the like of the first light LS1 and the second light LS2 may be determined in consideration of the material and the thickness of the layer that is to be etched. For example, when viewed on a plane, an area, in which the first light LS1 is provided, may be larger than an area, in which the second light LS2 is provided, and at least a portion of the area, in which the second light LS2 is provided, may overlap the area, in which the first light LS1 is provided. In an embodiment, the area, in which the second light LS2 is provided, may be provided in the area, in which the first light LS1 is provided.

When the first light LS1 is irradiated onto the wafer WF, a portion of the wafer WF, for example, the element layer DV, may be etched by the first light LS1. The first groove GV1 may be formed on the wafer WF due to the etching of the element layer DV. An upper surface of the substrate layer SUB may be exposed by the first groove GV1. That is, a bottom surface of the first groove GV1 may correspond to an upper surface of the substrate layer SUB. The first groove GV1 may have a size corresponding to the width of the first light LS1.

When the second light LS2 is irradiated onto the wafer WF, a portion of the wafer WF, for example, the substrate layer SUB, may be etched by the second light LS2. Due to the etching of the substrate layer SUB, the second groove GV2 may be formed in the substrate layer SUB. The second groove GV2 may have a depth from the upper surface toward the rear surface of the substrate layer SUB. The depth of the second groove GV2 may be smaller than the thickness of the substrate layer SUB. That is, the second groove GV2 may not pass through the substrate layer SUB, and the substrate layer SUB may be connected as an integral part without being separated in an area in which the second groove GV2 is not formed. The second groove GV2 may have a shape, a width of which decreases from the upper surface to the rear surface of the substrate layer SUB. For example, the second groove GV2 may have a cone shape, an apex of which is located at a bottom thereof when viewed in a cross section. The second groove GV2 may act as a crack site, at which a crack may occur due to an external physical impact.

In an embodiment, when the first light LS1 and the second light LS2 are irradiated substantially simultaneously while the first light LS1 is placed ahead of the second light LS2 within a single scan, the first groove GV1 and the second groove GV2 may be formed simultaneously. When the first groove GV1 and the second groove GV2 are formed simultaneously, required time and process costs for forming the first and second grooves GV1 and GV2 may be reduced compared to a process of forming the second groove GV2 after the formation of the first groove GV1.

In an embodiment, the process of forming the first groove GV1 and the process of forming the second groove GV2 may be performed by using a single laser cutting apparatus. In particular, they may be performed by using the laser cutting apparatus according to the embodiments described above.

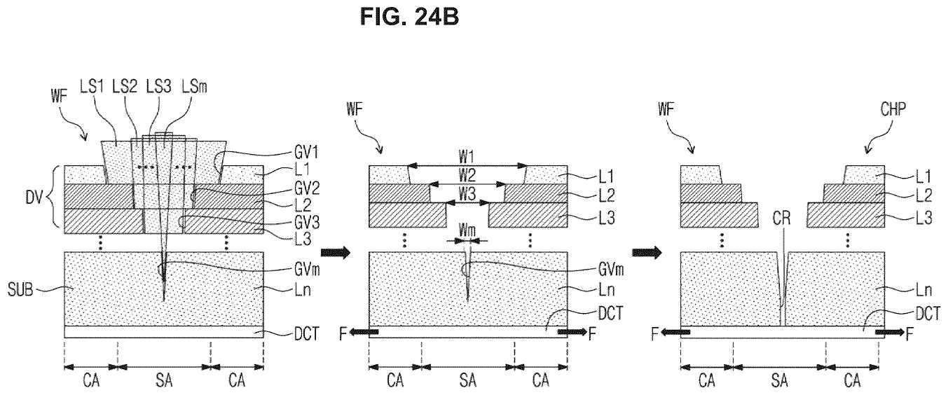

FIGS. 24A and 24B are schematic views illustrating an operation of processing a wafer having a plurality of element layers by using a laser, and illustrate cases, in which the laser cutting apparatus is implemented in first and second modes, respectively. The drawings illustrated in FIGS. 24A and 24B differ in the irradiation timings of the first to n-th lights and the formation order of the first to m-th grooves GVm according to the first and second modes, and in other respects, the wafer WF may be processed in substantially the same manner as described in the above example embodiment(s).

Referring to FIGS. 24A and 24B, in an embodiment of the present disclosure, the wafer WF may include a plurality of layers including a substrate layer SUB. The wafer WF may include a substrate layer SUB, and element layers DV that are laminated on the substrate layer SUB. For example, the wafer WF may include “n” layers (“n” is a natural number that is greater than or equal to 2) that are sequentially laminated from top to bottom. That is, the wafer WF may include a first layer L1, a second layer L2, . . . , and an n-th layer Ln that are disposed from top, and the first to (n−1)-th layers L1 to Ln−1 may be element layers DV, and the n-th layer Ln may be a substrate layer SUB.

In an embodiment, each layer in the “n” layers may be a layer, in which grooves may be formed with the laser scan under the same conditions without changing the laser irradiation conditions. In an embodiment, each layer in the “n” layers may have different materials of components that form the inside thereof, strengths of the components, and/or the like from other layers, and thus, two different layers may not be etched simultaneously under one etching condition.

Furthermore, in an embodiment, one layer in the “n” layers may be a layer that is formed with is an element that is different from those formed in adjacent layers. Each element may be an active element or a passive element.

In an embodiment, each element layer DV may be manufactured in a form of semiconductor chips. Each element layer DV configured in the form of semiconductor chips may include a separate substrate, and semiconductor elements that are formed on the substrate. Layers including the separate substrate and the semiconductor elements may be laminated on the substrate layer SUB as is or with being inverted. A plurality of element layers DV each manufactured in the form of semiconductor chips may also be prepared and may be sequentially laminated on the substrate layer SUB.

In an embodiment, a sum of two or more layers in the “n” layers may constitute one element. In this case, each of the layers that constitute one element may be etched under different etching conditions. In this case, the irradiation conditions for the laser beam for each layer may vary in at least any one of the variables such as power, pulse repetition rate, scan speed, focus position, width, shape of light, number of branches of light, wavelength, and/or position of the optical axis of the laser beam.

However, the laser irradiation conditions for a plurality of layers need not be the same for each layer, and in other embodiments, two or more layers may be etched simultaneously by adjusting variables such as power, pulse repetition rate, scan speed, focus position, width, shape of light, number of light branches, wavelength, and/or position of the optical axis of the laser beam.

In an embodiment, “m” lights (“m” is a natural number that is greater than or equal to 2) may be irradiated to “n” layers. For example, a first light LS1, a second light LS2, . . . , and an m-th light LSm may be irradiated.

Here, the irradiation angles of the first light LS1, the second light LS2, . . . , and m-th light LSm may have larger values with respect to an upper surface of a layer that is to be etched, from the first light LS1, the second light LS2, . . . , to m-th light LSm. In other words, the light that is placed ahead may be irradiated at a smaller angle with respect to the upper surface of the layer that is to be removed than the light that is placed behind. When the irradiation angle of the first light LS1 placed ahead is larger than that of the light placed behind, it may be difficult to efficiently propagate into the groove GV thereafter due to the inclination of the side surface of the groove GV.

In an embodiment, “n” and “m” may be the same or different. The drawing illustrates, by way of example, that n and m are the same.

The first light LS1 may be irradiated onto the first layer L1 to form the first groove GV1. The first groove GV1 may be formed by etching and removing a portion of the first layer L1 by the first light LS1, and may have a width substantially corresponding to a first width W1. A portion of an upper surface of the second layer L2 may be exposed by the first groove GV1, and the bottom surface of the first groove GV1 may be the upper surface of the second layer L2. The second light LS2 may be irradiated onto the second layer L2 to form the second groove GV2 in the second layer L2. The second groove GV2 may be formed by etching a portion of the second layer L2 by the second light LS2, and may have a width corresponding to the second width W2. In the same manner, the third, fourth, . . . , and n-th grooves GV3 GV4, . . . , and GVn may be formed in the third, fourth, . . . , and n-th layers L3, L4, . . . , and Ln by the third, fourth, . . . , and m-th lights LS3, LS4, . . . , and LSm, respectively. When a j-th light (j being a natural number where 1<j<m) is irradiated to an i-th layer Li (i being a natural number where 1<i<n) to form a j-th groove GVj, a (j+1)-th light Lj+1 may be irradiated into the j-th groove GVj formed by the j-th light. Here, a j-th width Wj of the j-th groove GVj may be greater than or at least equal to a (j+1)-th width Wj+1 of a (j+1)-th groove GVj+1. This is because when the j-th width Wj of the j-th groove GVj is smaller than the (j+1)-th width Wj+1 of the (j+1)-th groove GVj+1, the (j+1)-th light LSj+1 may not be sufficiently irradiated because it is obstructed by a side wall of the j-th groove GVj.

In an embodiment, the (j+1)-th light LSj+1 may be irradiated to a portion of a bottom surface of the j-th groove GVj. In other words, when viewed on a plane, an area, to which the j-th light LSj is provided, may be larger than an area, to which the (j+1)-th light LSj+1 is provided, and at least a portion of the area, to which the (j+1)-th light LSj+1 is provided, may overlap the area, to which the j-th light LSj is provided. In an embodiment, the area, to which the (j+1)-th light LSj+1 is provided, may be provided within and completely overlap the area, to which the j-th light LSj is provided.

In an embodiment, the first to (n−1)-th grooves GV1, GV2, . . . , and GVn−1 may be provided in a form, in which they pass through corresponding layers upward and downward, i.e., in a full cutting form. In contrast, the m-th groove GVm may be provided in a form of passing through only a portion of the substrate layer SUB, i.e., in a partial cutting (e.g., half-cutting). The m-th groove GVm may have a depth in a direction from the upper surface toward the rear surface of the substrate layer SUB. The depth of the m-th groove GVm may be smaller than the thickness of the substrate layer SUB. That is, the m-th groove GVm may not pass through the substrate layer SUB, and the substrate layer SUB may be connected as an integral part without being separated in an area, in which the m-th groove GVm is not formed. The m-th groove GVm may have a shape, a width of which decreases from the upper surface to the rear surface of the substrate layer SUB. For example, the m-th groove GVm may have a cone shape (or a “V” shape), an apex of which is located at a bottom thereof when viewed in a cross section. Alternatively, the m-th groove GVm may have an “I” shape with a narrow width and a constant width. The m-th groove GVm may act as a crack site, at which a crack may occur due to an external physical impact. In the substrate layer SUB, when a layer, in which the m-th groove GVm is formed, is assumed to be an upper layer and a layer, in which the m-th groove GVm is not formed, is assumed to be a lower layer, the thickness of the lower layer may be 1 micrometer or more.

In an embodiment, a bottom surface of the (m−1)-th groove GVm−1 may be flat. When the bottom surface of the first groove GV1 is not flat, scattering, reflection, or refraction of the m-th light LSm may occur due to an uneven bottom surface of the (m−1)-th groove GVm−1 during the irradiation of the m-th light LSm for the formation of a crack site, and accordingly, the m-th groove GVm may be formed at an undesired point, and the shape of the m-th groove GVm may also be different from an intended one.

In an embodiment, “n” and “m” may be different values. When “n” is greater than “m”, two or more layers may be etched by one light, and when “n” is less than “m”, one layer may be etched by two or more lights. The number of layers of the wafer WF and the number of laser lights may be set in consideration of the properties of each layer. For example, by differently setting the laser irradiation conditions depending on the materials of the components that constitute each layer, the strengths of the components, the differences in the thermal expansion coefficient between interfaces, and/or the like, it is possible to prevent or reduce lateral cracks that occur at an interface between adjacent layers.

In an embodiment, the wafer WF may be placed on the dicing tape DCT after the grooves are formed by using a laser, or grooves may be formed by using a laser while being placed on the dicing tape DCT. The drawings illustrate an example in which the wafer WF is disposed on the dicing tape DCT and grooves are formed while the wafer WF is placed on the dicing tape DCT.

As illustrated, after the n-th groove GVn is formed, the dicing tape DCT may be expanded such that individual semiconductor chips CHP are divided from the wafer WF. An expansion direction of the dicing tape DCT is indicated by an arrow in the drawing. When the dicing tape DCT is expanded, an external force “F” is applied to the wafer WF due to the expansion. A crack may occur in a downward direction from an apex of the n-th groove GVn due to the external force “F”. Two adjacent semiconductor chips CHP may be separated due to the crack, and eventually, the wafer WF may be cut into individual semiconductor chips CHP along the scribe lane area SA due to the expansion of the dicing tape DCT.

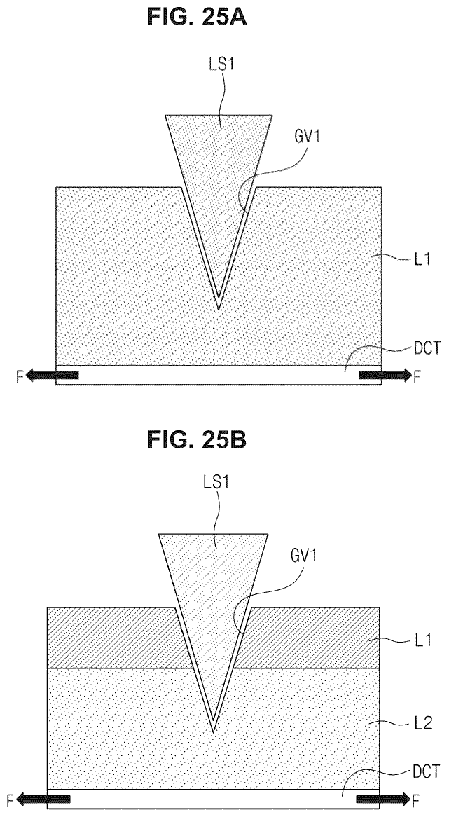

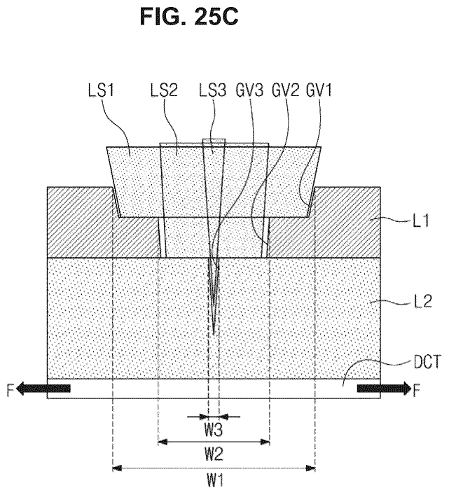

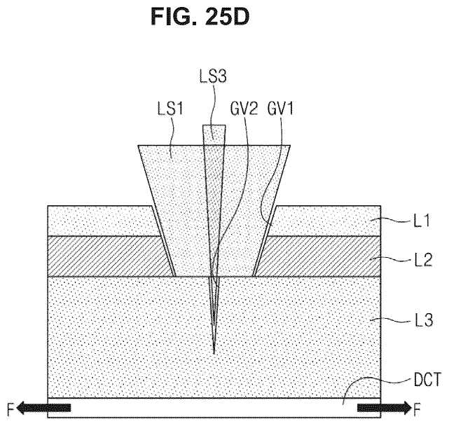

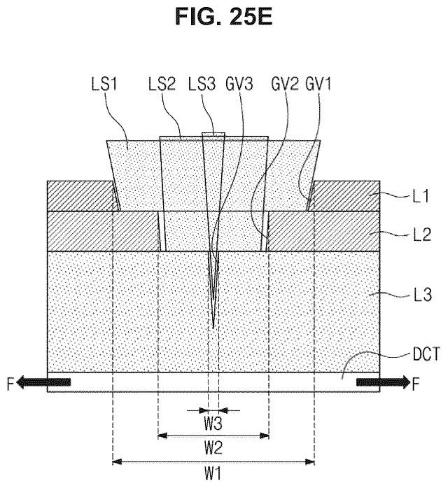

FIGS. 25A to 25E are schematic views illustrating a method for processing a wafer according to an embodiment of the present disclosure.

Referring to FIG. 25A, a groove may be formed by irradiating a single light onto the wafer provided as a single layer. That is, a first groove GV1 may be formed by irradiating a first light LS1 onto the wafer including only of a first layer L1. Here, the wafer may be a substrate layer SUB or an element layer DV. Thereafter, the wafer may be cut into two semiconductor chips due to a crack (not illustrated) generated by the first groove GV1 through expansion of the dicing tape DCT.

Referring to FIG. 25B, a groove may be formed by irradiating a single light onto the wafer provided as two layers. That is, a first groove GV1 may be formed by irradiating a first light LS1 onto the wafer including of a first layer L1 and a second layer L2. The first layer L1 and the second layer L2 may share the first groove GV1. An inner surface corresponding to the first groove GV1 in the first layer L1 may be substantially coplanar with an inner surface corresponding to the first groove GV1 in the second layer L2.

Thereafter, the wafer may be cut into two semiconductor chips due to a crack (not illustrated) generated by the first groove GV1 through expansion of the dicing tape DCT.

Referring to FIG. 25C, three grooves GV may be formed by irradiating three types of light onto the wafer provided in two layers. That is, first to third grooves GV1, GV2, and GV3 may be formed by irradiating the first to third lights LS1, LS2, and LS3 onto the wafer formed of the first and second layers L1 and L2. The first light LS1 and the second light LS2 may be irradiated onto the first layer L1. The first to third lights LS1, SL2, and LS3 may be lights having first to third widths W1, W2, and W3, respectively, and the first to third widths W1, W2, and W3 may have sequentially smaller values. Here, the first light LS1 may not pass through the first layer L1 and may etch only a portion from an upper surface of the first layer L1 to a specific depth. Accordingly, the first groove GV1 may be formed to a depth that is smaller than the thickness of the first layer L1. The second light LS2 may be provided in the area, in which the first groove GV1 is formed, and may form the second groove GV2 that passes through remaining portions of the first layer L1. The second groove GV2 may expose a portion of the upper surface of the second layer L2.

Thereafter, the wafer may be cut into two semiconductor chips due to a crack (not illustrated) generated by the third groove GV3 through expansion of the dicing tape DCT.

Referring to FIG. 25D, two grooves GV may be formed by irradiating two types of light onto the wafer provided in three layers. That is, the first groove GV1 and the second groove GV2 may be formed by irradiating the first light LS1 and the second light LS2 onto the wafer including of the first layer L1 and the second layer L2. In this case, the first groove GV1 may be provided to the first layer L1 and the second layer L2 to expose a portion of an upper surface of the third layer L3. The first layer L1 and the second layer L2 may share the first groove GV1. An inner surface corresponding to the first groove GV1 in the first layer L1 may be substantially coplanar with an inner surface corresponding to the first groove GV1 in the second layer L2.

Thereafter, the wafer may be cut into two semiconductor chips due to a crack (not illustrated) generated by the second groove GV2 through expansion of the dicing tape DCT.

Referring to FIG. 25E, three grooves GV may be formed by irradiating three types of light onto the wafer provided in three layers. That is, the first to third grooves GV1 to GV3 may be formed by irradiating the first to third lights LS1, LS2, and LS3 onto the wafer including of the first to third layer L1, L2, and L3. The first to third lights LS1, SL2, and LS3 may be lights having first to third widths W1, W2, and W3, respectively, and the first to third widths W1, W2, and W3 may have sequentially smaller values. In this case, the first groove GV1 may be provided to the first layer L1 to expose a portion of an upper surface of the second layer L2. The second groove GV2 may be provided to the second layer L2 to expose a portion of an upper surface of the third layer L3.

Thereafter, the wafer may be cut into two semiconductor chips due to a crack (not illustrated) generated by the third groove GV3 through expansion of the dicing tape DCT.

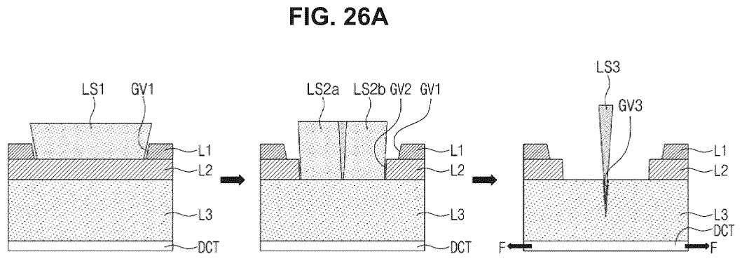

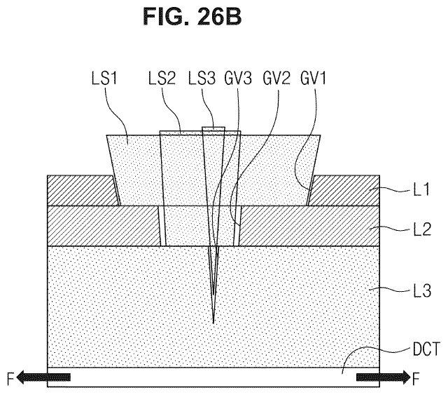

FIGS. 26A and 26B are schematic views illustrating a method for processing a wafer according to an embodiment of the present disclosure, and are schematic views illustrating operations of processing a wafer having a plurality of element layers by using a laser.

Referring to FIG. 26A, the first light LS1 may be irradiated onto the first layer L1 to form the first groove GV1. Here, the first light LS1 may have a width corresponding to the width of the first groove GV1.

The second light LS2 may be irradiated onto the second layer L2 to form the second groove GV2. In this case, the second light LS2 may include two lights having a single width to be formed, that is, a first sub-light LS2a and a second sub-light LS2b.

Here, the first sub-light LS2a and the second sub-light LS2b may each have a width that is different from the width of the second groove GV2. For example, the first sub-light LS2a and the second sub-light LS2b may each have a width that is smaller than the width of the second groove GV2. The first sub-light LS2a and the second sub-light LS2b may or may not overlap each other, and a total width of areas, to which the first sub-light LS2a and the second sub-light LS2b are irradiated, may substantially correspond to the width of the second groove GV2.

In an embodiment, the first sub-light LS2a and the second sub-light LS2b may be irradiated to the second layer L2 simultaneously. However, the present disclosure is not limited thereto, and the first and second sub-lights LS2a and LS2b may be irradiated sequentially over time. For example, the first sub-light LS2a may be irradiated first and the second sub-light LS2b may be irradiated later. The first sub-light LS2a and the second sub-light LS2b may be lights having the same properties or lights having different properties.

The third light LS3 may be irradiated onto the third layer L3 to form the third groove GV3.

Thereafter, the wafer may be cut into two semiconductor chips due to a crack (not illustrated) generated by the third groove GV3 through expansion of the dicing tape DCT.

In the embodiment, it is illustrated that the second groove GV2 is formed by two sub-lights LS2a and LS2b, but the present disclosure is not limited thereto, and one or more grooves may be formed by a greater number of sub-lights. Furthermore, in the embodiment, it is illustrated that only the second groove GV2 is formed by two sub-lights LS2a and LS2b, but the present disclosure is not limited thereto, and it is apparent that other grooves in other layers may also be formed by multi-lights, i.e., a plurality of sub-lights.

In an embodiment, at least some of the lights irradiated to the layers may have different optical axes from the remaining ones. In other words, the optical axes of the lights irradiated to the layers may or may not coincide with each other. For example, in the embodiment illustrated in FIG. 26A, the optical axes of the first light LS1 and the third light LS3 may coincide with each other, but the optical axes of the first light LS1 and the second light LS2 may not coincide. In particular, in the case of the second light LS2, the optical axes of the first and second sub-lights LS2a and LS2b may not coincide with each other.

Referring to FIG. 26B, the first light LS1 to the third light LS3 may be irradiated onto the first layer L1 to the third layer L3 to form the first to third grooves GV1, GV2, and GV3. In this case, the first to third light LS1 to LS3 may all have different optical axes.

As described above, a process of forming one groove may be performed by using either a single light or multiple lights. For example, one groove may be formed by irradiating a single light having a specific width corresponding to the groove that is to be manufactured. Alternatively, one groove may be formed by irradiating multiple lights having a specific width that is smaller than the width of the groove that is to be manufactured. In this case, the multiple lights may be a plurality of lights having the same width or a plurality of lights having different widths.

Furthermore, in an embodiment, when a plurality of grooves are formed, the optical axes of the lights corresponding to the grooves may all be the same or at least some may be different. When the plurality of sub-lights are used to form one groove, the optical axes of the respective sub-lights may all be the same or at least some may be different.

In an embodiment of the present disclosure, the laser irradiation conditions may vary depending on the material and properties of a layer, in which a groove is to be formed. For example, laser beams under different conditions may be irradiated in a process of forming a groove in a substrate layer including silicon, and/or the like and a process of forming a groove in an element layer DV including conductive wires (e.g., metal wires) and insulating films. The substrate layer including silicon, and/or the like is a highly brittle material, and the element layer including the conductive wires and the insulating films may have a lower brittleness but a greater ductility than those of the substrate layer SUB.

The element layer may be disposed on the substrate layer, and the grooves having a wider width than that of the substrate layer may be formed as described above. The grooves may have a structure with a flat bottom. Whether the groove of the structure has good quality (e.g., non-defective) may be determined depending on whether there are residues (especially residues of the conductive wiring) of the element layer in the groove and a number of occurrences of damage per unit length due to heat generated during grooving. In other words, a presence or an absence of two defects may be determined, and one defect may be a presence (especially the presence of residues of the conductive wiring) of residues of the element layer in the groove due to insufficient grooving, the other defect is an occurrence of HAZ(s) outside of a certain range, and damage to the protective film. The occurrence or absence of the defects may be affected by derived parameters calculated from an output (power) (W), a pulse repetition rate (frequency) (kHz), a width of the laser beam (um), a number of divisions of the beam, and a number of processing times.

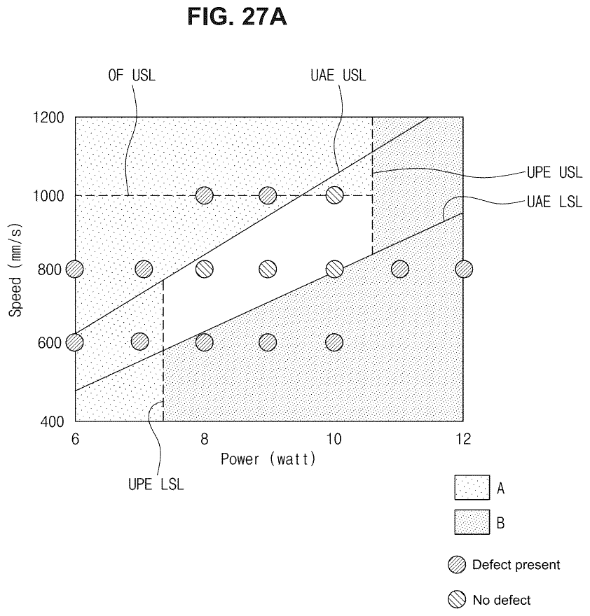

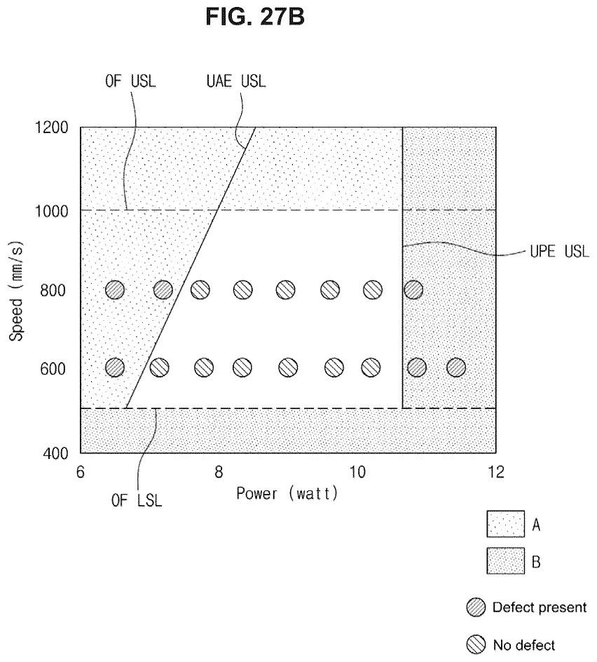

FIG. 27A illustrates a presence or an absence of grooving defects in a of areas depending on laser irradiation conditions when grooves are to be formed in an element layer, and FIG. 27B illustrates a presence or an absence of grooving defects in a form of areas according to laser irradiation conditions when grooves are to be formed in a substrate layer.

Portions marked with circles in FIGS. 27A and 27B are those that were identified to have defects through actual experiments, and indicate the presence or absence of defects. Defects include the presence (especially the presence of residues of the conductive wiring) of residues of the element layer due to insufficient grooving (indicated by area “A”), and the occurrence of HAZ(s) outside of a certain range, and damage to the protective film (indicated by area “B”).

In FIG. 27A, UPE is the energy per unit pulse, UAE is the energy per unit area, and OF is the pulse-to-pulse overlap ratio, which may be defined by an equation defined in Table 1 below.

TABLE 1

| UPE (unit pulse energy) | UAE (unit area energy) | OF (overlap factor) |
|---|---|---|
| $UP \text{?} ( \text{?} ) = \frac{Power}{Frequency \cdot Split \#}$ | $UAE ( \text{?} / {m}^{2} ) = \frac{Power}{Speed} \times \frac{Pass \#}{Beam Width}$ | $OF = 1 - \frac{Speed}{Frequency \times Beam Width}$ |

$\text{?} \text{indicates text missing or illegible when filed}$

In the equation, split #means a split number, and path #means the number of scans. OF is an arbitrary value that represents a degree of overlap of lights during scanning. Furthermore, in FIG. 27A, UPE and UAE are functions that are proportional to the power of the laser, and OF is a function that is proportional to the scan speed of the laser, and is not represented as a separate numerical value, but is represented in an arbitrary unit for convenience of description. Here, LSL means a lower limit that indicates a defect, and USL means an upper limit that indicates a defect.

Referring to FIG. 27A, whether laser cutting is successful or not in grooving the element layer may be determined depending on the energy per unit pulse, the energy per unit area, and the degree of overlap of lights during scanning.

To perform grooving without defects on the element layer during laser cutting, the energy per unit area has to be in an area that is greater than the lower limit and is less than the upper limit, and when it is out of that area, a laser cutting defect occurs. When the energy per unit area is greater than the upper limit, there is a problem of insufficient grooving, and when the energy per unit area is less than the lower limit, there is a problem of damage to the HAZ or the protective film. An inclination of the upper limit per unit area with respect to the power of the energy per unit area is greater than the inclination of the lower limit per unit area with respect to the power of the energy per unit area.

Furthermore, to perform grooving without defects on the element layer during laser cutting, the energy per unit pulse has to be in an area that is greater than the lower limit and is less than the upper limit, and when it is out of that area, a laser cutting defect occurs. When the energy per unit pulse is less than the lower limit, there is a problem of insufficient grooving, and when it is greater than the upper limit, there is a problem of damage to the HAZ or the protective film.

In addition, there is a problem that grooving is not sufficient when the energy per unit area is less than its upper limit and the degree of overlap of the lights during scanning is greater than its upper limit.

Referring to FIG. 27B, whether laser cutting for the substrate layer is successful or not when grooving the substrate layer may be determined depending on the energy per unit pulse, the energy per unit area, and the degree of overlap of lights during scanning. However, conditions for the energy per unit pulse, the energy per unit area, and the degree of overlap of lights during scanning to perform grooving without defects on the substrate layer are very different from conditions for those for laser cutting to perform grooving without defects on the element layer.

To perform grooving without defects on the substrate layer during laser cutting, the energy per unit area has to be in an area that is greater than the lower limit and is less than the upper limit, and when it is out of that area, a laser cutting defect occurs. When the energy per unit area is greater than the upper limit, there is a problem of damage to the HAZ or the protective film, and when the energy per unit area is less than the lower limit, there is a problem of insufficient grooving. Here, the upper limit of the energy per unit area with respect to the power of the energy per unit area has a specific inclination with respect to the power, but the lower limit of the energy per unit area does not appear for a range of power of the energy per unit area shown.

Furthermore, to perform grooving without defects on the substrate layer during laser cutting, the energy per unit pulse has to be in an area that is greater than the lower limit and is less than the upper limit, and when it is out of that area, a laser cutting defect occurs. When the energy per unit pulse is greater than the upper limit, there is a problem of damage to the HAZ or the protective film, but no upper limit of the energy per unit pulse was found for a range of power of the energy per unit area shown.

In addition, there is a problem that grooving is not sufficient when the energy per unit area is less than its upper limit and the degree of overlap of the lights during scanning is greater than its upper limit, and there is a problem that the HAZ or the protective film is damaged when the energy per unit area is greater than its upper limit or the degree of overlap of the lights during scanning is less than its lower limit.

When a semiconductor chip is manufactured through the above-described method, defects that may occur during the process of cutting the wafer may be minimized or prevented compared to a method for cutting the wafer by using a blade. In particular, when the wafer is cut by using a blade, yield of the semiconductor chip decreases due to crack defects, occurrence of foreign substances, decreased chip strength, and increased chipping risk, but when a semiconductor chip is manufactured by the manufacturing method according to an embodiment of the present disclosure, such problems may be solved.

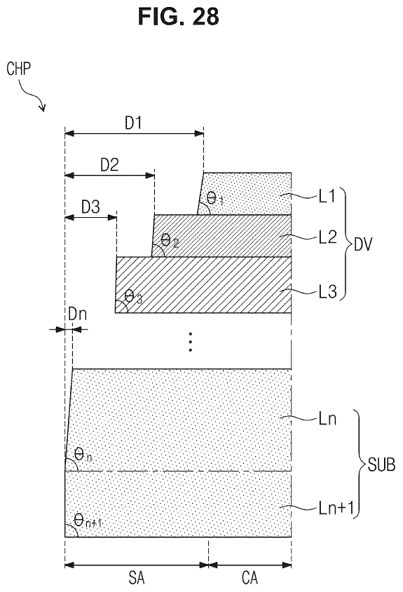

FIG. 28 is a schematic view illustrating a semiconductor element manufactured through the above-described method for manufacturing a semiconductor device.

Referring to FIG. 28, the semiconductor chip CHP may include a substrate layer SUB and a plurality of element layers DV that are sequentially laminated on the substrate layer SUB. In an embodiment, the semiconductor chip CHP may include n+1 layers (“n” is a natural number) that are sequentially laminated from top to bottom.

The semiconductor chip CHP may include a chip area CA including semiconductor elements, and/or the like, and a peripheral area that is adjacent to the chip area CA. In an embodiment, the peripheral area corresponds to an area corresponding to a scribe lane area SA before cutting of the wafer, and thus, the peripheral area will be regarded as a scribe lane area SA hereinafter.

The semiconductor chip CHP may include a first layer L1, a second layer L2, . . . , and an (n+1)-th layer Ln+1 disposed from top, and the first to (n−1)-th layers L1 to Ln−1 may be element layers DV, and the n-th layer Ln and the (n+1)-th layers Ln+1 may be substrate layers SUB. The n-th layer Ln and the (n+1)-th layer Ln+1 may be formed as a non-separated integral part, and may be the substrate layer SUB, for example, formed of silicon and/or the like. In an embodiment, the first to (n−1)-th layers L1 to Ln−1 may have a thickness of about 1 um or more, or about 5 um or more, or about 10 um or more.

A side surface of the semiconductor chip CHP may have different shapes depending on a wafer processing method. A shape of the semiconductor chip CHP may have different shapes depending on the irradiation conditions of laser lights. In an embodiment, in the scribe lane area SA, the layer, to which the laser beams are irradiated, and the layer, to which a physical external force is applied without laser beams, may have different side surfaces. That is, side surfaces of the first layer to n-th layer L1 to Ln, to which the laser beams are irradiated, and the side surface of the (n+1)-th layer Ln+1, to which a laser beam is not irradiated, have different shapes.

Each of the side surfaces of the first to n-th layers L1 to Ln may be an inclined surface with respect to a lower surface of a corresponding layer. The side surface of the (n+1)-th layer Ln+1, to which a laser beam is not irradiated, may be a perpendicular surface with respect to a lower surface of the substrate layer SUB. Here, the side surface of the (n+1)-th layer Ln+1 may be an inclined surface that is not completely vertical, but a degree of inclination may be small and may correspond to a substantially vertical surface.

In an embodiment, the inclined surface of each of the first to n-th layers L1 to Ln may have a greater inclination angle with respect to the lower surface of the corresponding layer from the first layer L1 to the n-th layer Ln. For example, the inclined surface of each of the first to n-th layers L1 to Ln may have an inclination angle that is closer to an angle close to a vertical line, that is, 90 degrees with respect to the lower surface of the corresponding layer from the first layer L1 to the n-th layer Ln. Here, the angles θ₁, θ₂, . . . , and θₙ of the inclined surfaces of the first to n-th layers L1 to Ln cannot exceed 90 degrees with respect to the lower surface of the corresponding layer.

The angles θ₁, θ₂, . . . , and θₙ₋₁ of the inclined surfaces of the first to (n−1)-th layers L1 to Ln−1 may have various values. The angles θ₁, θ₂, . . . , and θₙ₋₁ of the inclined surfaces of the first to (n−1)-th layers L1 to Ln−1 may be about 55 degrees to about 87 degrees, or about 60 degrees to about 85 degrees. The inclination angle θₙ of the n-th layer Ln may be greater than the inclination angles θ₁, θ₂, . . . , and θₙ₋₁, and may be about 85 degrees or more and less than 90 degrees, or about 80 degrees or more and less than about 90 degrees. The inclination angle θₙ₋₁ of the (n+1)-th layer may be greater than the inclination angles θ₁, θ₂, . . . , and θₙ of the first to n-th layers 1, 2, . . . , and Ln, and may have an angle that is close to the vertical line. That is, the inclination angle θₙ₊₁ of the (n+1)-th layer Ln+1 may be about 85 degrees or more. The inclination angle θₙ₊₁ of the (n+1)-th layer Ln+1 that is close to the vertical line is due to the separation without a separate mechanical optical processing by utilizing the tension of the dicing tape DCT during the semiconductor chip CHP manufacturing process. Here, the side surface of the (n+1)-th layer Ln+1 may be flat without any trace of processing, such as irradiation of laser beams.

In an embodiment, the side surfaces of the first layer L1 to the n-th layer Ln may become more distant from the chip area CA from the first layer L1 to the n-th layer Ln. Furthermore, the side surfaces of the first to n-th layers L1 to Ln may become closer to an outer boundary of the semiconductor chip CHP from the first to n-th layers L1 to Ln. When distances between uppermost points on the side surfaces of the first to n-th layers L1 to Ln with respect to an outermost boundary of a lowermost layer of the semiconductor chip CHP, that is, the (n+1)-th layer Ln+1 is assumed to be first to n-th distances D1, D2, . . . , and Dn, the first to n-th distances D1, D2, . . . , and Dn may decrease, that is, become closer to the outer boundary of the semiconductor chip CHP from the first layer to the n-th layers L1 to Ln. In other words, the side surfaces of the layers laminated may become more distant from the outermost boundary of the (n+1)-th layer Ln+1 from a lower side to an upper side of the laminated layers. Here, an (i+1)-th (1<i<n) distance Di+1 cannot exceed an i-th distance Di. That is, the (i+1)-th distance Di+1 may be less than or equal to the i-th distance Di.

The inclination angles θ₁, θ₂, . . . , and θₙ₋₁ of the inclined surfaces of the first to n-th layers L1 to Ln and the distances D1, D2, . . . , and Dn from the outer boundary of the semiconductor chip CHP may be due to the conditions for grooving using the laser beams. For example, the inclination angles of the inclined surfaces may be changed in response to the shapes of the lights irradiated onto the first to n-th layers L1 to Ln. That is, in the processes of forming the side surfaces of the first layer L1 to the n-th layer Ln, the irradiation angles at which the first light LS1, the second light LS2, . . . , and the m-th light LSm are irradiated with respect to upper surfaces of layers that are to be irradiated and removed may have larger values from the first light LS1, the second light LS2, . . . , to the m-th light LSm. Accordingly, the angles θ₁, θ₂, . . . , and θₙ₋₁ of the inclined surfaces of the first to n-th layers L1 to Ln may approach 90 degrees from the first to n-th layers L1 to Ln. Furthermore, the distances from the outer boundary of the semiconductor chip CHP to the first to n-th layers L1 to Ln may increase in proportion to the widths of the lights irradiated to the first to n-th layers L1 to Ln.

In an embodiment, the (n+1)-th layer Ln+1 may have a thickness a specific thickness or more, for example, a thickness of 1 micrometer or more. However, the (n+1)-th layer Ln+1 may have a thickness that allows dividing by a dicing tape during a dividing process for the wafer WF. For example, the (n+1)-th layer Ln+1 may have a thickness of about 40 um or less, or about 30 um or less, or about 20 um or less. The n-th layer Ln may have a thickness of about 1 um to about 300 um, or about 2 um to 200 um, or about 5 um to about 150 um. The first to (n−1)-th layers 1, 2, . . . , and Ln−1 may have various thicknesses as element layers. For example, the first to (n−1)-th layers 1, 2, . . . , and Ln−1 may each have a thickness of about 5 um to about 300 um, or about 10 um to about 200 um, or about 15 um to about 150 um.

In an embodiment, the first to n-th layers 1, 2, . . . , and Ln may include a heat-affected zone (HAZ) that is formed from the grooves, to which the laser beams are irradiated. The heat-affected zone is an area, in which a change in material and/or configuration occurs due to heat when the laser beams are irradiated. The HAZ may be formed to a depth of about 0.01 um or more, for example, about 0.5 um or about 0.1 um or more, from the side surface toward the interior thereof. For example, when the substrate layer SUB is formed of silicon, a silicon crystal damage area may exist to a depth of about 0.1 um or more from the side surface in the case of the n-th layer Ln. The (n+1)-th layer Ln+1 may be a zone, in which no laser beam is irradiated, and no HAZ may exist.

In an embodiment of the present disclosure, each of the second to n-th layers 2, 3, . . . , and Ln may have an upper flat surface that is exposed while not being covered by a layer disposed directly thereon. For example, an i-th layer Li may have an upper flat surface that is exposed while not being covered by an (i−1)-th layer Li−1. This is due to a change in the width of the lights irradiated to each layer during the grooving process for the wafer WF. In an embodiment, the flat surfaces of the first to (n−1)-th layers L1 to Ln−1 may have a width of about 0.1 um to about 15 um, or about 0.2 um to about 12 um, or about 0.5 um to about 10 um when viewed on a cross section.

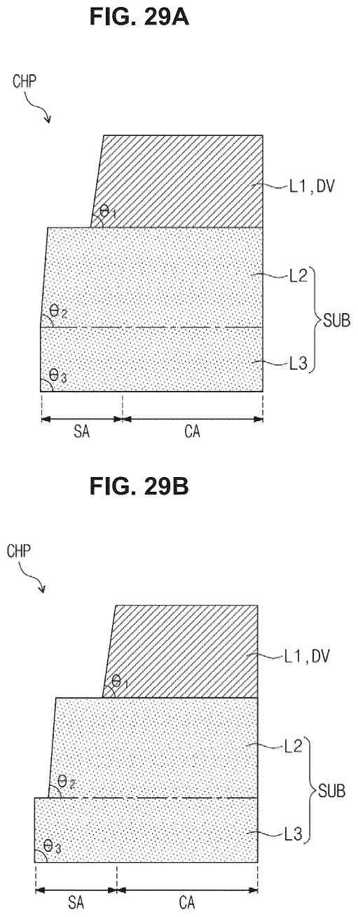

FIG. 29A and FIG. 29B are schematic views illustrating, by way of example, a semiconductor element manufactured by a method for manufacturing a semiconductor element, FIG. 29A illustrates an example, in which a V-shaped groove is formed in a substrate layer SUB, and FIG. 29B illustrates an example, in which an I-shaped (or substantially I-shaped) groove is formed in the substrate layer SUB.

Referring to FIG. 29A, the semiconductor chip CHP may have a three-layer laminated structure. In the semiconductor chip CHP, the first layer L1 may be an element layer DV, and the second layer L2 and the third layer L3 may correspond to the substrate layer SUB. The second layer L2 may be disposed on the third layer L3. The second layer L2 and the third layer L3 may be formed as an integral part without being separated.

The side surfaces of the first layer L1 and the second layer L2 may have different shapes. The first layer L1 and the second layer L2 may have inclined surfaces with respect to the lower surfaces of the first layer L1 and the second layer L2, respectively. The side surface of the third layer L3 may be a substantially vertical plane with respect to the lower surface of the third layer L3.

The inclined surface of the second layer L2 may have a greater inclination angle θ₂ than that of the first layer L1, but may have a value that is smaller than 90 degrees. In an embodiment, an inclination angle θ₁ of the first layer L1 may be about 60 degrees to about 85 degrees. An inclination angle θ₂ of the second layer L2 may have a greater value than the inclination angle θ₁ of the first layer L1, and may be about 60 degrees to about 85 degrees. An inclination angle θ₃ of the third layer L3 may be a value that is close to the vertical line, and may be about 85 degrees to about 90 degrees.

In an embodiment, the first layer L1 may include various circuits, wirings, and insulating films as an element layer DV, and may have a thickness of about 15 um to about 150 um. The second layer L2 may have a thickness of about 5 um to about 50 um. The third layer L3 may have a thickness of about 5 um to about 20 um.

The side surface of the first layer L1 may be more distant from the outer boundary of the semiconductor chip CHP than the side surface of the second layer L2. The second layer L2 may cover the third layer L3. Accordingly, an upper flat surface that is exposed may not be provided on the third layer L3.

Referring to FIG. 29B, similar to FIG. 29A, the semiconductor chip CHP may have a three-layer laminated structure. In the semiconductor chip CHP, the first layer L1 may be an element layer DV, and the second layer L2 and the third layer L3 may correspond to the substrate layer SUB. The second layer L2 may be disposed on the third layer L3. The second layer L2 and the third layer L3 may be formed as an integral part without being separated.

The side surfaces of the first layer L1 and the second layer L2 may have different shapes. The side surface of the first layer L1 may be an inclined surface with respect to the lower surface of the first layer L1, and the side surfaces of the second layer L2 and the third layer L3 may be substantially perpendicular surfaces with respect to respective lower surfaces thereof. However, the side surface of the second layer L2 may be substantially close to a vertical plane but may not be a complete vertical plane, and in this case, the side surface of the second layer L2 may have a smaller inclination angle than the side surface of the third layer L3.

In an embodiment, the inclination angle θ₁ of the first layer L1 may be about 60 degrees to about 85 degrees. The inclination angle θ₂ of the second layer L2 may have a greater value than the inclination angle θ₁ of the first layer L1, and may be about 80 degrees to about 89 degrees. The inclination angle θ₃ of the third layer L3 may be a value that is close to the vertical line, and may be about 85 degrees to about 90 degrees.

In an embodiment, the first layer L1 may include various circuits, wirings, and insulating films as an element layer DV, and may have a thickness of about 15 um to about 150 um. The second layer L2 may have a thickness of about 5 um to about 50 um. The third layer L3 may have a thickness of about 5 um to about 20 um.

The side surface of the first layer L1 may be more distant from the outer boundary of the semiconductor chip CHP than the side surface of the second layer L2. The second layer L2 may not completely cover the third layer L3, and a portion of the upper surface of the third layer L3 may be exposed. Accordingly, an upper flat surface that is exposed may be provided on the third layer L3.

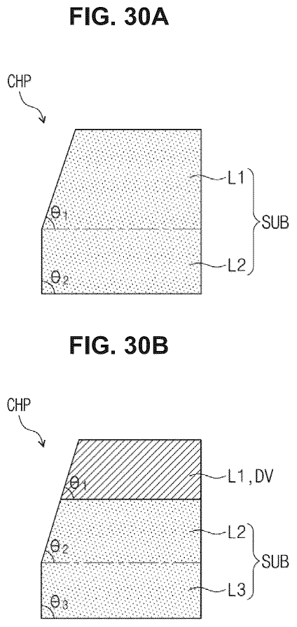

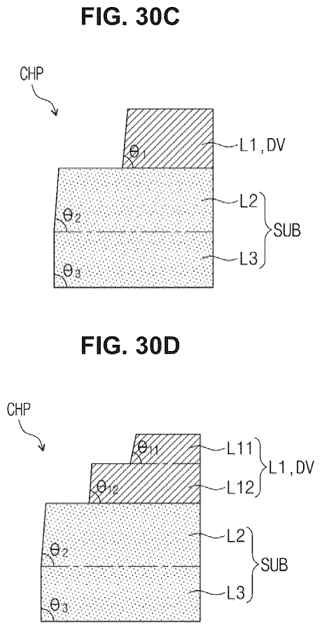

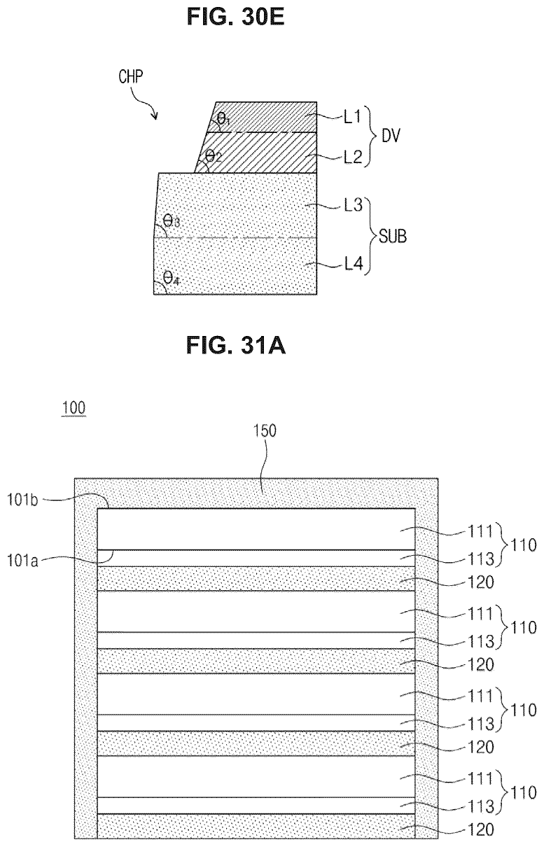

FIGS. 30A to 30E are schematic views illustrating, by way of example, semiconductor elements manufactured through the method for manufacturing semiconductor elements of the present disclosure, and illustrate semiconductor chips CHP corresponding to FIGS. 25A to 25E, respectively.

Referring to FIG. 30A, the semiconductor chip CHP may have a structure, in which two layers, that is, the first layer L1 and the second layer L2 are laminated. The first layer L1 and the second layer L2 may correspond to one of the element layer DV or the substrate layer SUB, and may be formed as a non-separated integral part.

The side surfaces of the first layer L1 and the second layer L2 may have different shapes. The first layer L1 may be an inclined surface with respect to the lower surface of the first layer L1. The side surface of the second layer L2 may be a substantially vertical plane with respect to the lower surface of the second layer L2. The inclination angle θ₂ of the side surface of the second layer L2 may have a greater value than the inclination angle θ₁ of the first layer L1, but may be about 60 degrees to about 85 degrees. The inclination angle θ₂ of the second layer L2 may be a value that is close to the vertical line, and may be about 85 degrees to about 90 degrees.

The first layer L1 may cover the second layer L2. Accordingly, an upper flat surface that is exposed may not be provided on the second layer L2.

Referring to FIG. 30C, the semiconductor chip CHP may have a structure, in which three layers, that is, the first to third layers L1, L2, and L3 are laminated.

In the semiconductor chip CHP, the first layer L1 may be the element layer DV, the second layer L2 and the third layer L3 may be the substrate layer SUB, and the second layer L2 and the third layer L3 may be formed as a non-separated integral part.

The side surfaces of the first layer L1 and the second layer L2 may be inclined surfaces, and may be substantially coplanar. The side surface of the third layer L3 may be a substantially vertical plane with respect to the lower surface of the third layer L3. The angles θ₁ and θ₂ of the side surfaces of the first layer L1 and the second layer L2 may be the same value that is smaller than the angle θ₃ of the side surface of the third layer L3, and the inclination angles θ₁ and θ₂ of the first layer L1 and the second layer L2 may be about 60 degrees to about 85 degrees. The inclination angle θ₃ of the third layer L3 may be a value that is close to the vertical line, and may be about 85 degrees to about 90 degrees.

The first layer L1 may completely cover the upper surface of the second layer L2, and the second layer L2 may entirely cover the upper surface of the third layer L3. Accordingly, an upper flat surface that is exposed may not be provided on the second layer L2 and the third layer L3.

Referring to FIG. 30C, the semiconductor chip CHP may have a structure, in which three layers, that is, the first to third layers L1, L2, and L3 are laminated.

In the semiconductor chip CHP, the first layer L1 may be the element layer DV, the second layer L2 and the third layer L3 may be a substrate layer SUB, and the second layer L2 and the third layer L3 may be formed as a non-separated integral part.

The side surface of the first layer L1 and the second layer L2 may be inclined surfaces, and may have different inclination angles. The inclination angle θ₁ of the first layer L1 may have a smaller value than the inclination angle θ₂ of the second layer L2, and the inclination angles θ₁ and θ₂ of the first layer L1 and the second layer L2 may be about 60 degrees to about 85 degrees. The inclination angle θ₃ of the third layer L3 may be a value that is close to the vertical line, and may be about 85 degrees to about 90 degrees.

The first layer L1 may cover a portion of the upper surface of the second layer L2, and an upper flat surface that is exposed may be provided at the uncovered portion of the second layer L2. The second layer L2 may cover the entire upper surface of the third layer L3. Accordingly, the third layer L3 may not be provided with an upper flat surface that is exposed.

Referring to FIG. 30D, the semiconductor chip CHP may have a structure, in which three layers, that is, the first to third layers L1, L2, and L3 are laminated.

In the semiconductor chip CHP, the first layer L1 may be the element layer DV, the second layer L2 and the third layer L3 may be the substrate layer SUB, and the second layer L2 and the third layer L3 may be formed as a non-separated integral part. The first layer L1 may include first and second sub-layers L11 and L12. The first sub-layer L11 may be provided on the second sub-layer L12.

Here, the side surfaces of each of the first sub-layer L11, the second sub-layer L12, and the second layer L2 may be inclined surfaces, and may have different inclination angles. The inclination angles of each of the side surfaces of the first sub-layer L11, the second sub-layer L12, and the second layer L2 with respect to the lower surfaces thereof may have larger values toward a lower side (that is, from the first sub-layer L11 to the second layer L2). For example, the inclination angle θ11 of the side surface of the first sub-layer L11 may be smaller than the inclination angle θ12 of the side surface of the second sub-layer L12, and the inclination angle θ12 of the side surface of the second sub-layer L12 may be smaller than the inclination angle θ₂ of the side surface of the second layer L2. The inclination angles of the side surfaces of the first sub-layer L11, the second sub-layer L12, and the second layer L2 may be provided at about 60 degrees to about 85 degrees within the above limits. The inclination angle θ₃ of the third layer L3 may be a value that is close to the vertical line, and may be about 85 degrees to about 90 degrees.

The first sub-layer L11 may cover a portion of an upper surface of the second sub-layer L12, and the upper surface of the second sub-layer L12 that is not covered may be provided as a flat surface. Furthermore, the second sub-layer L12 may cover a portion of the upper surface of the second layer L2, and the upper surface of the second layer L2 that is not covered may be provided as a flat surface that is exposed. The second layer L2 may cover the entire upper surface of the third layer L3. Accordingly, the third layer L3 may not be provided with an upper flat surface that is exposed.

In this way, at least one layer of the plurality of layers of the semiconductor chip CHP may include two or more sub-layers, and thus, may include two or more side surfaces having different inclination angles.

Referring to FIG. 30E, the semiconductor chip CHP may have a structure, in which four layers, that is, the first to fourth layers L1, L2, L3, and L4 are laminated.

In a semiconductor chip CHP, the first layer L1 and the second layer L2 may be element layers DV, and the third layer L3 and the fourth layer L4 may be substrate layers SUB. The third layer L3 and the fourth layer L4 may be formed as a non-separated integral part.

The side surfaces of the first layer L1 and the second layer L2 may be inclined surfaces, and may be substantially coplanar. The side surface of the third layer L3 may be an inclined surface. A side surface of the fourth layer L4 may be a substantially vertical plane with respect to a lower surface of the fourth layer L4. The inclination angles θ₁ and θ₂ of the side surfaces of the first layer L1 and the second layer L2 may have values that are smaller than the inclination angle θ₃ of the side surface of the third layer L3, and the inclination angle θ₃ of the side surface of the third layer L3 may have a value that is smaller than the inclination angle θ₄ of the side surface of the fourth layer L4. The inclination angles of the first to third layers L1 to L3 may be about 60 degrees to about 85 degrees. The inclination angle of the fourth layer L4 may be a value that is close to the vertical line, and may be about 85 degrees to about 90 degrees.

The first layer L1 may completely cover the upper surface of the second layer L2, and thus, an upper flat surface that is exposed may not be formed on the upper surface of the second layer L2. The second layer L2 may cover a portion of the upper surface of the third layer L3, and the upper surface of the third layer L3 that is not covered may be provided as an upper flat surface that is exposed. The third layer L3 may completely cover an upper surface of the fourth layer L4.

The present disclosure may be employed in a process of forming various semiconductor chips. For example, the semiconductor chip may be a logic semiconductor chip, a memory semiconductor chip, or any combination thereof. For example, the logic semiconductor chip may include, for example but not limited to, an application processor (AP), a microprocessor, a central processing unit (CPU), a controller, a graphic processor unit (GPU), a system-on-a-chip (SoC), or an application specific integrated circuit (ASIC). Furthermore, the memory semiconductor chip may include a volatile memory such as, for example but not limited to, a dynamic random access memory (DRAM), a static random access memory (SRAM), or a nonvolatile memory, such as a phase-change random access memory (PRAM), a magneto-resistive random access memory (MRAM), a ferroelectric random access memory (FeRAM), or a resistive random access memory (RRAM).

Hereinafter, one of the various semiconductor chips described above will be described, and a process for manufacturing the same by using a laser cutting method will be described.

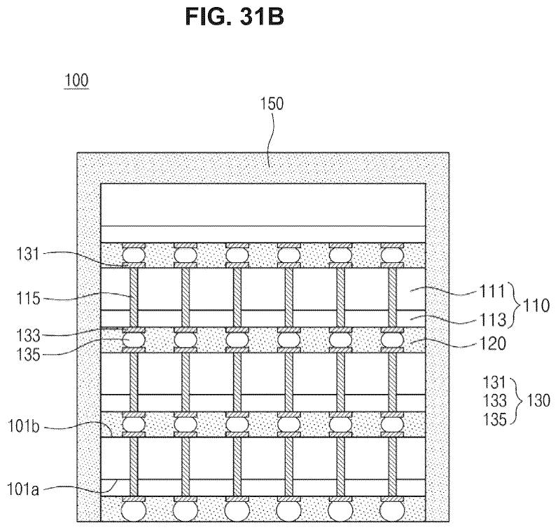

FIG. 31A is a cross-sectional view illustrating a semiconductor element according to an embodiment of the present disclosure, and FIG. 31B is a cross-sectional view specifically illustrating the semiconductor element of FIG. 31A.

Referring to FIGS. 31A and 31B, a semiconductor device 100 according to an embodiment of the present disclosure may include a plurality of semiconductor chips 110, for example, four semiconductor chips 110. The plurality of semiconductor chips 110 may be sequentially laminated with adhesive layers 120 interposed therebetween.

The semiconductor chips 110 may be logic chips and/or memory chips. For example, the plurality of semiconductor chips 110 may all be the same type of memory chips, or some of the plurality of semiconductor chips 110 may be memory chips and others may be logic chips. The memory chip may be, for example, a volatile memory, such as a dynamic random access memory (DRAM), a static random access memory (SRAM), or a nonvolatile memory, such as a phase-change random access memory (PRAM), a magneto-resistive random access memory (MRAM), a ferroelectric random access memory (FeRAM), and/or a resistive random access memory (RRAM), but not limited thereto. In an embodiment of the present disclosure, the semiconductor chips 110 may be a high bandwidth memory (HBM) DRAM. Furthermore, the logic chip, for example, may be a microprocessor, an analog element, and/or a digital signal processor, but not limited thereto.

In FIGS. 31A and 31B, the semiconductor device 100, in which four semiconductor chips 110 are laminated, is illustrated by way of example, but the number of semiconductor chips 110 laminated in the semiconductor device 100 is not limited thereto. For example, two, three, or five or more semiconductor chips 110 may be laminated in the semiconductor device 100.

Each of the semiconductor chips 110 may include a chip substrate 111, and an element layer 113 that is provided on the chip substrate 111.

The chip substrate 111 may include a front surface 101a and a rear surface 101b. The front surface 101a and the rear surface 101b are surfaces that face each other, the front surface 101a may be a surface on which an element layer 113 is formed, and the rear surface 101b may be an opposite surface of the front surface 101a. The front surface 101a may be an active surface, on which a plurality of integrated circuits are formed, and the rear surface 101b may be an inactive surface.

The chip substrate 111, for example, may be a doped or undoped silicon (Si) substrate. In other embodiments, the chip substrate 111 may include other semiconductor materials such as, for example but not limited to, germanium, compound semiconductors including silicon carbide, gallium arsenide, gallium phosphide, indium phosphide, indium arsenide compounds, and/or indium antimony compounds, hybrid semiconductors including SiGe, GaAsP, AlInAs, AlGaAs, GaInAs, GaInP, and/or GaInAsP, or any combination thereof. The chip substrate 111 may be formed of a single layer or multiple layers. In an embodiment, the chip substrate 111 may have a silicon on insulator (SOI) structure. For example, the chip substrate 111 may include a buried oxide (BOX) layer. The chip substrate 111 may include a conductive area, for example, a well doped with an impurity, or a structure doped with an impurity. Furthermore, the chip substrate 111 may have various element isolation structures, such as a shallow trench isolation (STI) structure.

The element layer 113 may be provided on the front surface 101a of the chip substrate 111. The element layer 113 may include a plurality of individual elements and/or wirings that connect the individual elements.

The semiconductor chips 110 may further include a through via 115, a first pad 131, and a second pad 133. The through via 115 may pass through the chip substrate 111 and extend from the front surface 101a toward the rear surface 101b of the chip substrate 111, or from the rear surface 101b toward the front surface 101a. The through via 115 may be connected to wirings (not illustrated) provided in the element layer 113 or may pass through the element layer 113 to be connected to the first pad 131 and/or the second pad 133. The through via 115, the first pad 131, and/or the second pad 133 may be directly connected to each other as illustrated, but may be electrically connected to each other through various other wirings (not illustrated).

In each semiconductor chip 110, the second pad 133 may be disposed on the element layer 113. The second pad 133 may be electrically connected to a wiring structure (not illustrated) in an interior of the element layer 113 or may be directly connected to the through via 115. The first pad 131 may be disposed on the rear surface 101b of the chip substrate 111 and may be electrically connected to the through via 115.

The first pads 131 and/or the second pads 133 may include, for example but not limited to, a metal, a metal nitride, a metal oxide, a metal silicide, a conductive carbon, or any combination thereof. For example, the first and/or the second pads 131 and 133 may include Ag, Al, AlN, Au, Be, Bi, Co, Cu, Hf, In, Mn, Mo, Ni, Pb, Pd, Pt, Rh, Re, Ru, Sn, Ta, TaN, Te, Ti, TiN, W, WN, Zn, Zr, or any combination thereof, but not limited to. In an embodiment, the first pads 131 and/or the second pads 133 may include, for example but not limited to, one of Al, Cu, Ni, W, Pt, or Au.

Two adjacent semiconductor chips 110 may be connected to each other by connectors 135. The connectors 135 may be provided between first and second pads 131 and 133 that face each other, between the two adjacent semiconductor chips 110. The connectors 135 that connect the two adjacent semiconductor chips 110 may include, for example but not limited to, at least one of a conductive bump, a conductive ball, a conductive pin, a conductive lead, a conductive pillar, or any combination thereof. For example, each of the connectors 135 may include an under bump metal (UBM) and a conductive bump.

The first pads 131, the second pads 133, and the connectors 135 may constitute connection terminals 130 that connect two adjacent semiconductor chips 110. The connection terminals 130 may be provided in adhesive layers 120. A space between the two semiconductor chips 110, which is provided with the connection terminals 130, may be filled with adhesive layers 120.

The connectors 135 connected to the rear surface 101b of the lowest semiconductor chip 110 may be used to electrically connect the semiconductor device 100 to external components such as a base substrate, an interposer, a package substrate, and/or the like, which will be described later. The connectors 135 connected to the rear surface 101b of the lowest semiconductor chip 110 may transmit at least one of a control signal, a power signal, or a ground signal for the operation of the semiconductor chips 110 from the outside to the direct circuit chips, receive a data signal that is to be stored in the semiconductor chips 110 from the outside, and/or provide data stored in the semiconductor chips 110 to the outside.

The first pads 131 may not be provided on the element layer 113 of an uppermost semiconductor chip 110. Because the first pads 131 are not provided in the uppermost semiconductor chip 110, the through vias 115 connected to the first pads 131 may not be provided in the uppermost semiconductor chip 110.

The adhesive layers 120 may attach two adjacent semiconductor chips 110 to each other, and may include a polymer material that is cured by heat and/or light. For example, the adhesive layers 120 may include a resin and a filler. In an embodiment, the resin may have thermosetting properties, and the filler may include fine particles such as silica, but the present disclosure is not limited thereto. In an embodiment, the adhesive layers 120 may be a non-conductive film (NCF). Furthermore, the adhesive layers 120 may be a die attach film (DAF).

The semiconductor device 100 may further include an encapsulating material 150 that surrounds an upper surface of the uppermost semiconductor chip 110, side surfaces of the semiconductor chips 110, and side surfaces of the adhesive layers 120. The encapsulating material 150 may be formed of materials, which may include, for example, an epoxy mold compound (EMC).

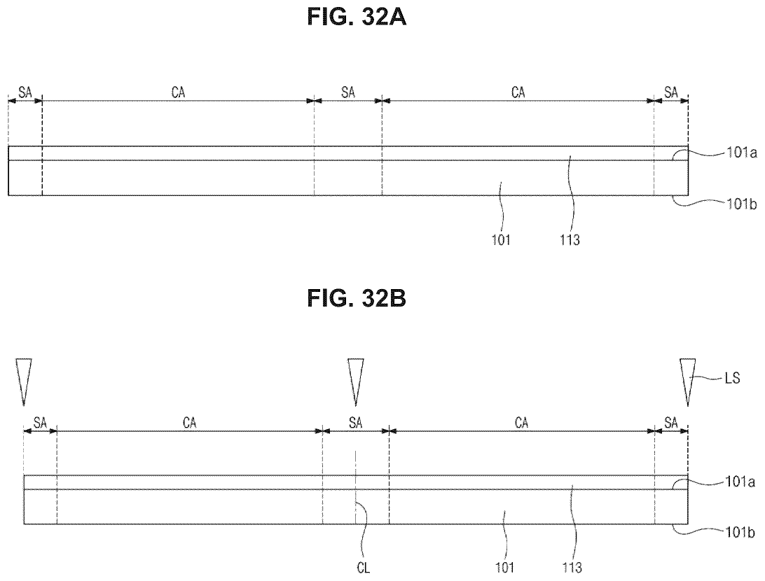

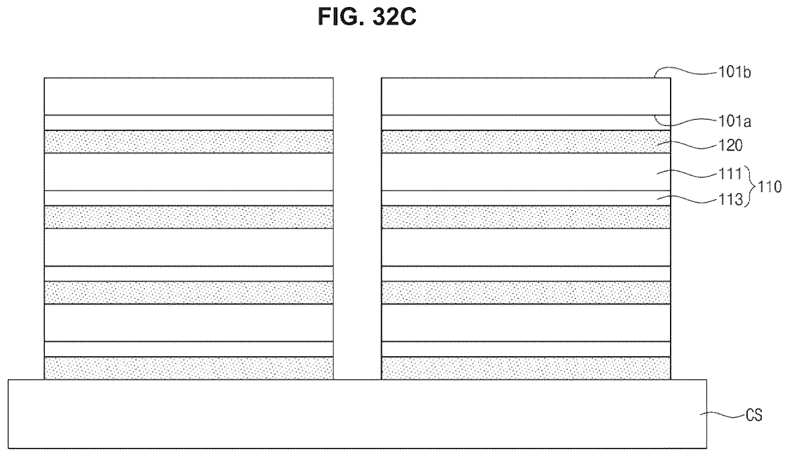

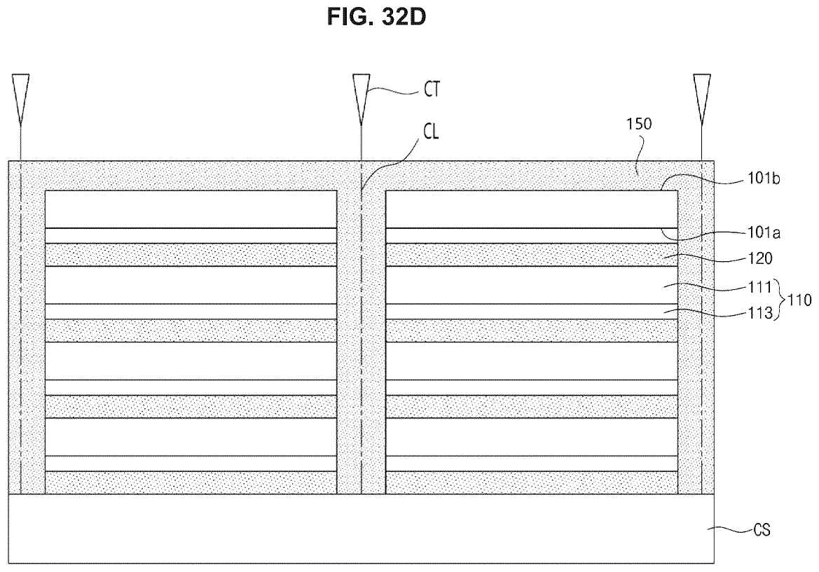

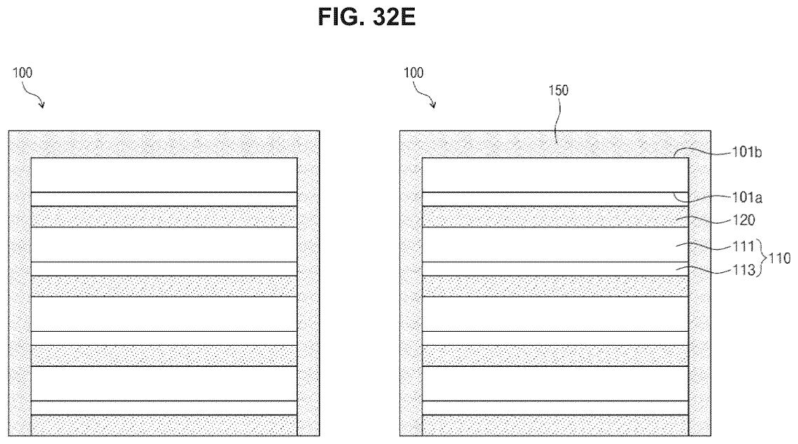

FIGS. 32A to 32E are views sequentially illustrating a method for manufacturing a semiconductor device by using the above-described embodiments. Hereinafter, the method for manufacturing a semiconductor device will be described in detail with reference to FIGS. 32A to 32E.

Referring to FIG. 32A, a substrate layer 101 for forming semiconductor chips is prepared. The substrate layer 101 may include chip areas CA and scribe lane areas SA between the chip areas CA.

The scribe lane area SA may surround four sides of the chip area CA when viewed in a plane. Widths of the scribe lane areas SA corresponding to the four side surfaces of the chip area CA may be the same or different.

The chip area CA may include an element layer 113 including a plurality of integrated circuits and/or wirings. The scribe lane area SA may be disposed outside the chip area CA in a form of surrounding the chip area CA.

Referring to FIG. 32B, the substrate layer 101 and the element layer 113 may be cut along a cutting line CL defined on the scribe lane area SA.

The cutting process of cutting the substrate layer 101 and the element layer 113 along the cutting line CL to separate them into semiconductor chips 110 may be a laser cutting process according to the embodiments described above.

Referring to FIG. 32C, a plurality of laminated semiconductor chips 110 may be placed on a carrier substrate CS.

Referring to FIG. 32D, an encapsulating material 150 that covers a plurality of laminated semiconductor chips 110 may be formed on the carrier substrate CS. The encapsulating material 150 may surround the upper surface of the uppermost semiconductor chip 110, side surfaces of the semiconductor chips 110, and side surfaces of the adhesive layers 120. The encapsulating material 150 may include various materials, which may include, for example, an epoxy mold compound (EMC).

The semiconductor elements, on which the encapsulating material 150 is formed, may then be cut along the cutting line CL by a cutter CT, and may be separated into individual semiconductor elements. The cutting process of cutting the encapsulating material 150 along the cutting line CL and separating it into semiconductor elements may be laser cutting according to the method described above. In an embodiment, the cutting process may be a process of performing cutting through grinding after laser irradiation.

Although not illustrated, the carrier substrate CS may be separated and removed from the semiconductor elements, on which the encapsulating material 150 is formed, before the semiconductor elements, on which the encapsulating material 150 is formed, are cut.

As illustrated in FIG. 3E, the plurality of individual semiconductor elements 100 may be manufactured by cutting semiconductor elements 100, on which the encapsulating material 150 is formed.

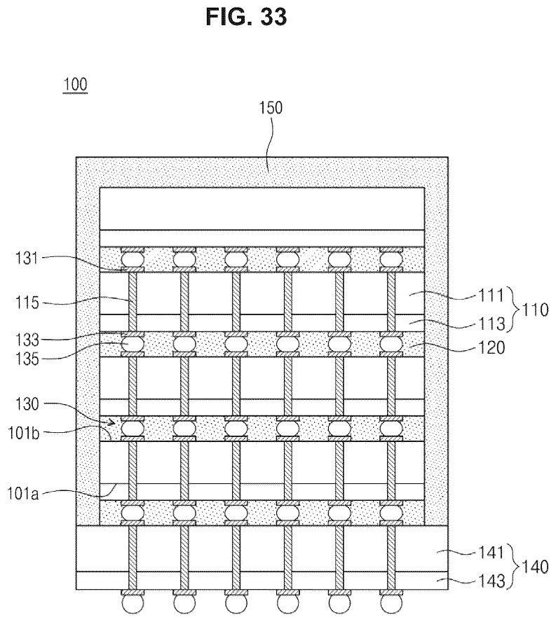

FIG. 33 illustrates semiconductor devices manufactured through the above-described method.

Referring to FIG. 33, the semiconductor device 100 according to an embodiment of the present disclosure may include a base chip 140 and a plurality of semiconductor chips 110. The plurality of semiconductor chips 110, for example, may include four semiconductor chips 110. The base chip 140 and the plurality of semiconductor chips 110 may be sequentially laminated with adhesive layers 120 interposed therebetween.

The base chip 140 may include a base chip substrate 141 and a base circuit layer 143 that is provided on the base chip substrate 141. Each of the semiconductor chips 110 may include a chip substrate 111 and an element layer 113. The base chip 140 and the semiconductor chips 110 may further include a through via 115, a first pad 131, and a second pad 133.

The base chip 140 and the semiconductor chips 110 may each be a logic chip and/or a memory chip. For example, the plurality of base chips 140 and the semiconductor chips 110 may all be the same type of memory chips, or some of the plurality of semiconductor chips 110 may be memory chips and others may be logic chips.

In an embodiment of the present disclosure, the base chips 140 and the semiconductor chips 110 may be a high bandwidth memory (HBM) DRAM. In this case, the base chip 140 may function as a buffer chip or a control chip, integrate signals of a plurality of DRAM chips and transmit them to the outside, and also transmit signals and power from the outside to the plurality of DRAM chips. For example, in an embodiment, the base chip 140 may correspond to a master chip. Each of the semiconductor chips 110 laminated on the base chip 140 may correspond to a slave chip.

An encapsulating material 150 that surrounds an upper surface of an uppermost semiconductor chip 110, side surfaces of the semiconductor chips 110, and side surfaces of the adhesive layers 120 may be provided on the base chips 140 and the semiconductor chips 110. The base chip 140 may have a larger area than the semiconductor chips 110 when viewed in a plane. The encapsulating material 150 may be provided on the base chip 140 and may not cover the side surface of the base chip 140. An outer surface of the encapsulating material 150 may define the same plane as an outer surface of the base chip 140.

A semiconductor element according to an embodiment of the present disclosure manufactured by the above-described method may be applied to various semiconductor packages.

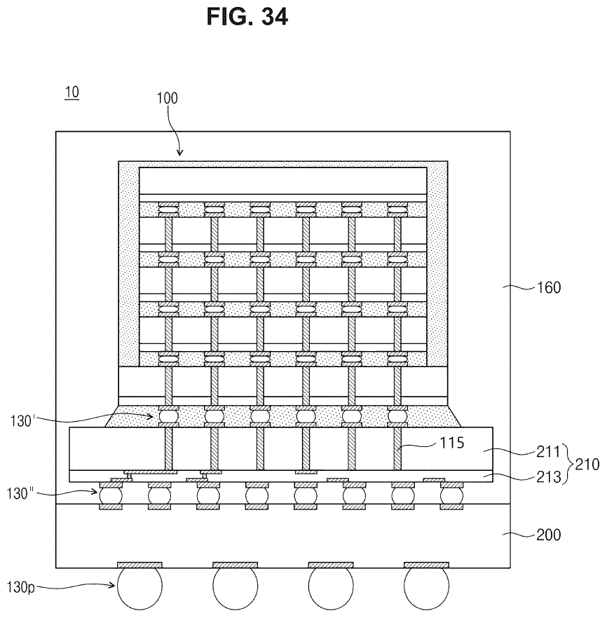

FIG. 34 illustrates a semiconductor package according to an embodiment of the present disclosure.

Referring to FIG. 34, a semiconductor package 10 according to an embodiment of the present disclosure may include a package substrate 200, a main semiconductor chip 210 that is mounted on the package substrate 200, and a semiconductor device 100 that is laminated on the main semiconductor chip 210.

The main semiconductor chip 210 may be a processor unit. The main semiconductor chip 210, for example, may be a micro processor unit (MPU) or a graphic processor unit (GPU). The main semiconductor chip 210 may include a main chip substrate 211, a circuit layer 213, and a main through vias 115. The main through vias 115 may have a structure that is similar to the through vias 115 of the base chip 140 and the semiconductor chips 110, and thus a detailed description thereof will be omitted.

Connection terminals 130′ and 130″ may be provided between the semiconductor device 100 and the main semiconductor chip 210 and between the main semiconductor chip 210 and the package substrate 200. The connection terminals 130′ and 130″ may include first and second pads that are provided to face each other, and connectors that are provided between the first and second pads. The connectors may be at least one of a conductive bump, a conductive ball, a conductive pin, a conductive lead, a conductive pillar, or any combination thereof. For example, each of the connectors may include a conductive filler and/or a solder ball.

An upper surface of the package substrate 200, the upper surface and side surfaces of the semiconductor device 100 and the main semiconductor chip 210 may be covered by an outer encapsulating material 160.

An external connection terminal 130p may be attached to a lower surface of the package substrate 200. The external connection terminal 130p may be attached, for example, on a lower surface pad. The external connection terminal 130p may be, for example, a solder ball or a bump. The external connection terminal 130p may electrically connect the semiconductor package 10 and an external device.

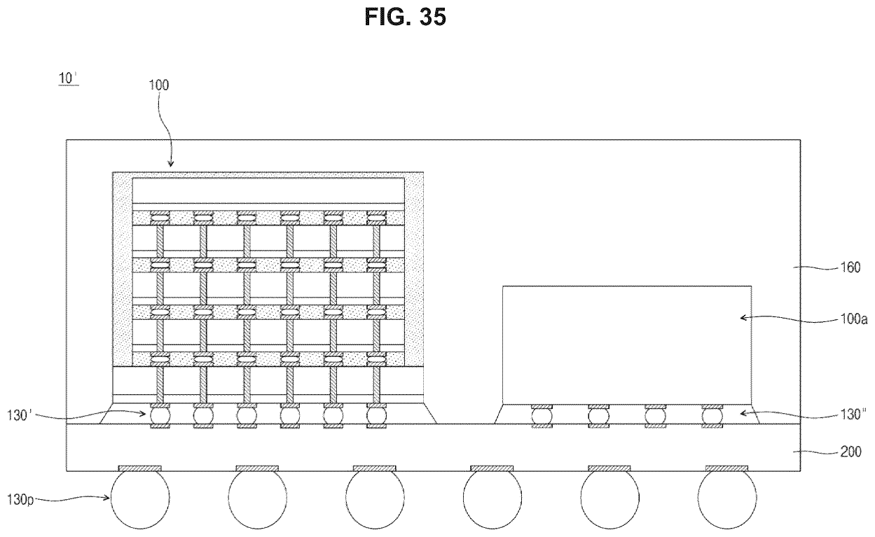

FIG. 35 illustrates a semiconductor package according to an embodiment of the present disclosure.

Referring to FIG. 35, a semiconductor package 10′ according to an embodiment of the present disclosure may include a package substrate 200, a first semiconductor device 100 that is mounted on the package substrate 200, and a second semiconductor device 100a.

The first semiconductor device 100 may be manufactured according to the above-described embodiment. In this embodiment, for convenience of description, semiconductor elements corresponding to FIGS. 6A and 6B are illustrated as examples.

The second semiconductor device 100a may be the same as or different from the first semiconductor device 100. In an embodiment, the second semiconductor device 100a may include a high bandwidth memory (HBM), a hybrid memory cube (HMC), a double data rate fifth-generation (DDR5) DRAM, or any combination thereof. Alternatively, the second semiconductor device 100a may include a microprocessor, a logic chip, an application processor, a graphics processing unit, a buffer chip, or any combination thereof.

An upper surface of the package substrate 200 and upper and side surfaces of the first and second semiconductor elements 100 and 100a may be covered by an outer encapsulating material 160.

An external connection terminal 130p may be attached to a lower surface of the package substrate 200. The external connection terminal 130p may be attached, for example, on a lower surface pad. The external connection terminal 130p may include, for example, a solder ball and/or a bump. The external connection terminal may electrically connect the semiconductor package 10′ and an external device.

The semiconductor element according to an embodiment of the present disclosure may be applied to the semiconductor package(s) as described above, but this is an example only and may be applied to various semiconductor elements and semiconductor packages other than the above one.

According to an embodiment of the present disclosure, a laser cutting method, by which a defect in a target object (e.g., wafer) may be reduced and required time and process costs may be reduced, is provided.

Although example embodiments of the present disclosure have been described for illustrative purposes, those skilled in the art will appreciate that various modifications, and substitutions are possible, without departing from the scope and spirit of the present disclosure as disclosed in the accompanying claims and their equivalents.

Accordingly, the technical scope of the present disclosure is not limited to the detailed description of this specification, but should be defined by the claims and their equivalents.

What is claimed is:

1. A wafer cutting method comprising:
forming a plurality of grooves by scanning a laser beam onto a front surface of a wafer, wherein the wafer comprises a plurality of layers, and the laser beam comprises at least two lights;
polishing a rear surface of the wafer;
mounting the wafer on a dicing tape; and
cutting the wafer by expanding the dicing tape,
wherein the forming the plurality of grooves comprises forming at least two grooves by using the at least two lights, the at least two grooves having different widths on at least two layers, among the plurality of layers of the wafer.

2. The wafer cutting method of claim 1, wherein the at least two lights comprise lights split along a scan direction and/or a direction being perpendicular to the scan direction.

3. The wafer cutting method of claim 2, wherein the at least two lights comprise lights split along the scan direction.

4. The wafer cutting method of claim 3, wherein a width of a light irradiated along the scan direction, among the at least two lights, is greater than a width of a light placed behind along the scan direction.

5. The wafer cutting method of claim 3, wherein the scanning the laser beam comprises sequentially or simultaneously irradiating the at least two lights onto the front surface of the wafer.

6. The wafer cutting method of claim 3, wherein the scanning the laser beam comprises irradiating a light placed ahead along the scan direction, among the at least two lights, onto a first area on the front surface of the wafer and a light placed behind along the scan direction, among the at least two lights, onto a second area overlapping the first area.

7. The wafer cutting method of claim 1, wherein a number of the plurality of layers of the wafer is the same as a number of the at least two lights.

8. The wafer cutting method of claim 1, wherein a number of the plurality of layers of the wafer is different from a number of the at least two lights.

9. The wafer cutting method of claim 1, wherein the wafer comprises a first layer to an n-th (n being a natural number greater than or equal to 2) layer sequentially laminated from an upper side toward a lower side of the wafer, the laser beam comprises a first light to an m-th (m being a natural number greater than or equal to 2) light, and
wherein the forming the plurality of grooves comprises forming a first groove to an m-th groove.

10. The wafer cutting method of claim 9, wherein the first layer to an (n−1)-th layer of the wafer are provided as element layers, and the n-th layer of the wafer is provided as a substrate layer.

11. The wafer cutting method of claim 10, wherein the forming the plurality of grooves comprises forming the first groove to an (m−1)-th groove to pass through corresponding the first to (n−1)-th layers, respectively, and the m-th groove to pass through only a portion of the n-th layer.

12. The wafer cutting method of claim 11, wherein m and n are different natural numbers.

13. The wafer cutting method of claim 2, wherein the at least two lights, when irradiated onto the wafer, differ from each other in at least one of: a power, a pulse repetition rate, a scan speed, a focus position, a light shape, a number of splits, a wavelength, an optical axis position, or a pulse width.

14. The wafer cutting method of claim 1, wherein the scanning the laser beam comprises sequentially or simultaneously irradiating the at least two lights from a single laser cutting apparatus onto the wafer.

15. The wafer cutting method of claim 1, wherein the scanning the laser beam comprises sequentially irradiating the at least two lights from at least two different laser cutting apparatuses onto the wafer y.

16. The wafer cutting method of claim 1, further comprising, before polishing the rear surface of the wafer:
laminating a protection sheet on the front surface of the wafer.

17. The wafer cutting method of claim 1, wherein the wafer comprises chip areas, and scribe lane areas provided between the chip areas, and
wherein the scanning the laser beam comprises irradiating the laser beam onto the wafer along a cutting line in a scribe lane area.

18. The wafer cutting method of claim 1, wherein the forming the plurality of grooves comprises:
selecting one of a first mode and a second mode;
based on the first mode being selected, irradiating a first light placed ahead, among the at least two lights, onto the front surface of the wafer, and irradiating a second light placed behind, among the at least two lights onto the front surface of the wafer, during a plurality of scans of the laser beam, and
based on the second mode being selected, irradiating all of the at least two lights onto the front surface of the wafer during one scan of the laser beam.

19. A wafer cutting method comprising:
polishing a rear surface of a wafer, the wafer comprising a plurality of layers;
mounting the wafer on a dicing tape;
forming a plurality of grooves by scanning a laser beam onto a front surface of the wafer, the laser beam comprising at least two lights; and
cutting the wafer by expanding the dicing tape,
wherein the forming the plurality of grooves comprises forming at least two grooves having different widths on at least two layers, among the plurality of layers of the wafer, by using the at least two lights.

20. The wafer cutting method of claim 19, further comprising, before the polishing of the rear surface of the wafer:
laminating a protection sheet on the front surface of the wafer.
